(19) United States
(12) Patent Application Publication
(10) Pub. No.: US 2022/0390837 A1
(43) Pub. Date: Dec. 8, 2022

(54) COLORING COMPOSITION, FILM, OPTICAL FILTER, SOLID-STATE IMAGING ELEMENT, AND IMAGE DISPLAY DEVICE

(71) Applicant: FUJIFILM Corporation, Tokyo (JP)

(72) Inventors: Hirotaka TAKISHITA, Haibara-gun (JP); Hiroaki IDEI, Haibara-gun (JP); Yoshinori TAGUCHI, Haibara-gun (JP)

(73) Assignee: FUJIFILM Corporation, Tokyo (JP)

(21) Appl. No.: 17/879,837

(22) Filed: Aug. 3, 2022

Related U.S. Application Data
(63) Continuation of application No. PCT/JP2021/003442, filed on Feb. 1, 2021.

(30) Foreign Application Priority Data
Feb. 5, 2020 (JP) 2020-017653

(51) Int. Cl. G03F 7/00; G03F 7/028; G02B 5/20

(52) U.S. Cl. CPC G03F 7/0007; G03F 7/028; G02B 5/208; H04N 9/04553

(57) ABSTRACT

Provided are a coloring composition including a colorant including a yellow colorant, a resin, and a solvent, in which a content of the yellow colorant in the colorant is 30% by mass or more, and the yellow colorant includes 15% by mass or more of an azomethine metal complex; a film formed of the coloring composition; an optical filter; a solid-state imaging element; and an image display device.

### CROSS-REFERENCE TO RELATED APPLICATIONS

This application is a Continuation of PCT International Application No. PCT/JP2021/003442 filed on Feb. 1, 2021, which claims priority under 35 U.S.C § 119(a) to Japanese Patent Application No. 2020-017653 filed on Feb. 5, 2020. Each of the above application(s) is hereby expressly incorporated by reference, in its entirety, into the present application.

### BACKGROUND OF THE INVENTION

### 1. Field of the Invention

The present invention relates to a coloring composition including a yellow colorant. The present invention further relates to a film formed of the coloring composition, an optical filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element. The color filter normally includes pixels of three primary colors of red, green, and blue, and acts to separate transmitted light into the three primary colors.

Colored pixels of each color of the color filter are manufactured by using a coloring composition containing a colorant. JP2001-188120A discloses an invention relating to a coloring composition for a color filter, which is composed of at least a pigment, a polymer, and a solvent, in which a content of a yellow pigment in the pigment component is 30% by weight, the yellow pigment is one or more selected from a quinophthalone pigment, an isoindoline pigment, an isoindolinone pigment, a nickel azo complex pigment, and a methine.azomethine pigment, and a specific surface area of the yellow pigment is 70 m²/g or more.

### SUMMARY OF THE INVENTION

In recent years, there has been an increasing demand for long-term reliability for devices equipped with an optical filter such as a color filter. Therefore, a film used for the optical filter is also required to have excellent long-term reliability.

On the other hand, in a case where a pixel is formed of a coloring composition containing a colorant and an optical filter including such a pixel is exposed to a high temperature and high humidity environment for a long period of time, a component such as the colorant included in the pixel may move to a member (such as a pixel of another color) adjacent to the pixel. Therefore, a known coloring composition in the related art is not sufficient in terms of long-term reliability of a film to be obtained, and there is room for improvement.

In addition, according to the study of the present inventor, a long-term reliability of a film to be obtained by using the coloring composition disclosed in Examples of JP2001-188120A is not sufficient, and there is room for improvement.

Therefore, an object of the present invention is to provide a coloring composition with which a film having excellent long-term reliability can be formed. Another object of the present invention is to provide a film formed of the coloring composition, an optical filter, a solid-state imaging element, and an image display device.

According to the studies conducted by the present inventors, it has been found that the above-described objects can be achieved by a coloring composition described below, thereby leading to the completion of the present invention. Therefore, the present invention provides the following.

<1> A coloring composition comprising:

a colorant including a yellow colorant;

a resin; and

a solvent,

in which a content of the yellow colorant in the colorant is 30% by mass or more, and

the yellow colorant includes 15% by mass or more of an azomethine metal complex.

<2> The coloring composition according to <1>,

in which a content of a quinophthalone compound in the yellow colorant is less than 50% by mass.

<3> The coloring composition according to <1> or <2>,

in which the azomethine metal complex includes at least one selected from an azomethine copper complex or an azomethine zinc complex.

<4> The coloring composition according to any one of <1> to <3>,

in which the colorant includes at least one selected from a green colorant or a red colorant.

<5> The coloring composition according to any one of <1> to <4>,

in which the colorant includes a green colorant, and

the green colorant includes a phthalocyanine compound.

<6> The coloring composition according to any one of <1> to <5>,

in which, in a case where a film having a thickness of 0.65 μm is formed of the coloring composition, a wavelength at which a light transmittance of the film is 50% exists in a wavelength range of 470 to 520 nm.

<7> The coloring composition according to any one of <1> to <6>, further comprising:

a polymerizable compound; and

a photopolymerization initiator.

<8> The coloring composition according to any one of <1> to <7>,

in which the coloring composition is used for a color filter or an infrared transmitting filter.

<9> A film obtained from the coloring composition according to any one of <1> to <8>.

<10> An optical filter comprising:

the film according to <9>.

<11> A solid-state imaging element comprising:

the film according to <9>.

<12> An image display device comprising:

the film according to <9>.

According to the present invention, it is possible to provide a coloring composition with which a film having excellent long-term reliability can be formed. It is also possible to provide a film formed of the coloring composition, an optical filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” is not only an independent step, but also includes a step which is not clearly distinguished from other steps in a case where an intended action of the step is obtained.

<Coloring Composition>

A coloring composition according to an embodiment of the present invention is a coloring composition including a colorant including a yellow colorant, a resin, and a solvent, in which a content of the yellow colorant in the colorant is 30% by mass or more, and the yellow colorant includes 15% by mass or more of an azomethine metal complex.

A film obtained by using the coloring composition according to the embodiment of the present invention can suppress a movement of the colorant included in the film to adjacent pixels or the like even in a case of being exposed to a high temperature and high humidity environment for a long period of time, so that the film is excellent in long-term reliability. The detailed reason for obtaining such an effect is not clear, but since the content of the yellow colorant in the colorant is 30% by mass or more and the yellow colorant includes 15% by mass or more of the azomethine metal complex, it is presumed that a film having a high film density can be formed. As a result, even in a case where the film is exposed to a high temperature and high humidity environment, it is presumed that an expansion or the like of the film can be suppressed. In addition, the azomethine metal complex easily interacts with a colorant other than the azomethine metal complex or a component other than the colorant included in the film, so that it is presumed that a strong interaction between the azomethine metal complex and components in the film can suppress the movement of the colorant and the like. For this reason, it is presumed that, with the coloring composition according to the embodiment of the present invention, a film having excellent long-term reliability can be formed.

The coloring composition according to the embodiment of the present invention is preferably used as a coloring composition for a color filter or an infrared transmitting filter. More specifically, the coloring composition according to the embodiment of the present invention can be preferably used as a coloring composition for forming a pixel of a color filter or a coloring composition for forming an infrared transmitting filter, and more preferably used as a coloring composition for forming a pixel of a color filter.

In a case where a film having a thickness of 0.65 μm is formed of the coloring composition according to the embodiment of the present invention, a wavelength at which a light transmittance of the film is 50% preferably exists in a wavelength range of 470 to 520 nm, more preferably exists in a wavelength range of 475 to 520 nm, and still more preferably exists in a wavelength range of 480 to 520 nm. Among these, the wavelength at which the light transmittance is 50% preferably exists in each wavelength range of 470 to 520 nm and wavelength range of 575 to 625 nm. In this aspect, a wavelength on a short wavelength side, at which the light transmittance is 50%, preferably exists in a wavelength range of 475 to 520 nm, and more preferably exists in a wavelength range of 480 to 520 nm. In addition, a wavelength on a long wavelength side, at which the light transmittance is 50%, preferably exists in a wavelength range of 580 to 620 nm, and more preferably exists in a wavelength range of 585 to 615 nm. A coloring composition with which a film having such spectral characteristics can be formed is preferably used as a coloring composition for forming a green pixel of a color filter.

Hereinafter, the respective components used in the coloring composition according to the embodiment of the present invention will be described.

<<Colorant>>

The coloring composition according to the embodiment of the present invention contains a colorant including a yellow colorant. As the yellow colorant, a yellow colorant containing an azomethine metal complex is used.

From the reason that it is easy to form a film having more excellent long-term reliability, the azomethine metal complex used in the yellow colorant is preferably a pigment. That is, the azomethine metal complex used in the yellow colorant is preferably an azomethine metal complex yellow pigment. In addition, from the reason that it is easy to form a film having more excellent long-term reliability, the azomethine metal complex preferably includes at least one selected from an azomethine copper complex or an azomethine zinc complex, and more preferably includes an azomethine copper complex. The azomethine metal complex may be used singly or in a combination of two or more kinds thereof. In addition, in a case where two or more kinds of the azomethine metal complexes are used in combination, the two or more kinds of the azomethine metal complexes may form a mixed crystal (solid solution).

Examples of the azomethine copper complex include Color Index (C. I.) Pigment Yellow 117 and 129. C. I. Pigment Yellow 117 is a compound represented by Formula (ACu-2), and C. I. Pigment Yellow 129 is a compound represented by Formula (ACu-1).

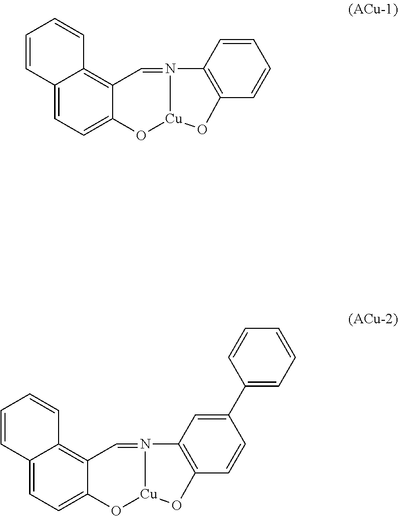

Examples of the azomethine zinc complex include a compound represented by Formula (AZN-1) and a compound represented by Formula (AZn-2).

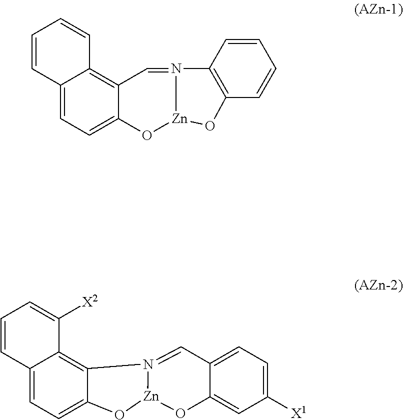

In Formula (AZn-2), X¹ and X² each independently represent a hydrogen atom, a halogen atom, or an alkoxy group.

Examples of the halogen atom represented by X¹ and X² include a fluorine atom, a chlorine atom, a bromine atom, and an iodine atom, and a chlorine atom or a bromine atom is preferable, and a chlorine atom is more preferable.

Examples of the alkoxy group represented by X¹ and X² include a methoxy group, an ethoxy group, a propyloxy group, an i-propyloxy group, a butyloxy group, an i-butyloxy group, an s-butyloxy group, a t-butyloxy group, a pentyloxy group, a 1-methylbutyloxy group, a 2-methylbutyloxy group, a 3-methylbutyloxy group, a 1,1-dimethylpropyloxy group, a 1,2-dimethylpropyloxy group, a 2,2-dimethylpropyloxy group, a 1-ethylpropyloxy group, a hexyloxy group, a 1-methylpentyloxy group, a 2-methylpentyloxy group, a 3-methylpentyloxy group, a 4-methylpentyloxy group, a 1,1-dimethylbutyloxy group, a 1,2-dimethylbutyloxy group, a 1,3-dimethylbutyloxy group, a 2,2-dimethylbutyloxy group, a 2,3-dimethylbutyloxy group, a 3,3-dimethylbutyloxy group, a 1-ethylbutyloxy group, a 2-ethylbutyloxy group, a 1,1,2-trimethylpropyloxy group, a 1,2,2-trimethylpropyloxy group, a 1-ethyl-1-methylpropyloxy group, and a 1-ethyl-2-methylpropyloxy group. Among these, an alkoxy group having 1 to 8 carbon atoms is a suitable example.

Specific examples of the compound represented by Formula (AZn-2) include compounds having the following structures.

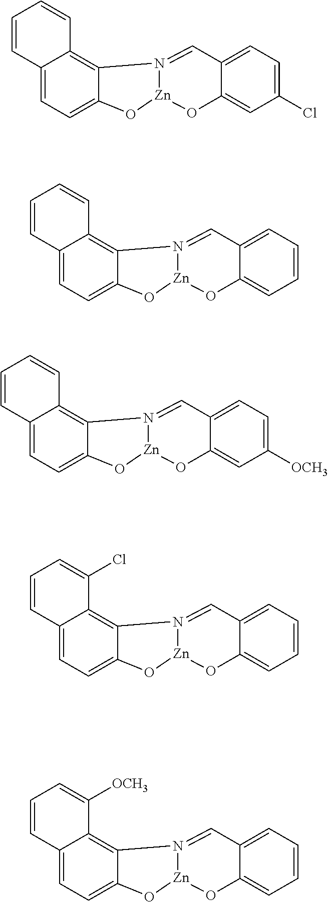

In addition, as the azomethine metal complex, it is also preferable to use a mixture or a mixed crystal (solid solution) of the compound represented by Formula (ACu-1) and the compound represented by Formula (AZn-1). According to this aspect, a color value is high, and it is possible to enhance light shielding properties at the same content. As the above-described mixture or mixed crystal (solid solution), it is preferable that the compound represented by Formula (AZn-1) is included in an amount of 10 to 900 parts by mass with respect to 100 parts by mass of the compound represented by Formula (ACu-1), and it is more preferable to be included in an amount of 25 to 400 parts by mass.

The colorant used in the coloring composition according to the embodiment of the present invention may further include a yellow colorant other than the azomethine metal complex. By further including a yellow colorant other than the azomethine metal complex, an optical filter having more excellent spectral characteristics can be obtained.

Examples of the yellow colorant other than the azomethine metal complex include an azo compound, an isoindoline compound, a pteridin compound, and a quinophthalone compound, and from the reason that it is easy to obtain a film having excellent spectral characteristics and light resistance, an azo compound, an isoindoline compound, or a pteridin compound is preferable, and an azo compound or an isoindoline compound is more preferable. In addition, from the reason that it is easy to obtain a film having excellent spectral characteristics and light resistance, an azo compound, the azo compound used as the yellow colorant is preferably an azo metal complex.

Specific examples of the yellow colorant other than the azomethine metal complex include yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 118, 119, 120, 123, 125, 126, 127, 128, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), and 236 (aminoketone-based).

In addition, as the yellow colorant other than the azomethine metal complex, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in JP6607427B, methine dyes described in JP2019-073695A, methine dyes described in JP2019-073696A, methine dyes described in JP2019-073697A, methine dyes described in JP2019-073698A, and the like can also be used. In addition, from the viewpoint of improving a color value, a multimerized compound of these compounds is also preferably used.

As the yellow colorant other than the azomethine metal complex, C. I. Pigment Yellow 139, 150, or 185 is preferable, and C. I. Pigment Yellow 150 is more preferable.

The colorant included in the coloring composition according to the embodiment of the present invention can further contain a colorant having a hue other than that of the yellow colorant. Examples of the colorant of other hues used in combination include a chromatic colorant such as a green colorant, a red colorant, a violet colorant, a blue colorant, and an orange colorant, and a black colorant. The colorant having other hues is preferably at least one selected from a green colorant, a red colorant, or an orange colorant, and more preferably at least one selected from a green colorant or a red colorant. Other colorants may be a pigment or a dye, but a pigment is preferable. In a case where a pigment is used as the other colorants, an interaction between the pigment as the other colorants and the azomethine metal complex as the yellow colorant can more effectively suppress the movement of the colorant included in the film to adjacent pixels or the like, and it is possible to form a film having more excellent long-term reliability. Such an effect is remarkable in a case where a green pigment is used as the other colorants, and the most remarkable effect is particularly obtained in a case where a phthalocyanine compound is used as the green pigment.

Examples of the red colorant include a diketopyrrolopyrrole compound, an anthraquinone compound, an azo compound, a naphthol compound, an azomethine compound, a xanthene compound, a quinacridone compound, a perylene compound, and a thioindigo compound, and from the reason that it is easy to form a film having more excellent long-term reliability, a diketopyrrolopyrrole compound, an anthraquinone compound, or an azo compound is preferable, and a diketopyrrolopyrrole compound is more preferable. In addition, the red colorant is preferably a pigment.

Specific examples of the red colorant include red pigments such as C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297. In addition, as the red colorant, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, red colorants described in JP6516119B, red colorant described in JP6525101B, and the like can also be used. In addition, as the red colorant, a compound having a structure that an aromatic ring group in which a group bonded with an oxygen atom, a sulfur atom, or a nitrogen atom is introduced to an aromatic ring is bonded to a diketopyrrolopyrrole skeleton can be used.

As the red colorant, C. I. Pigment Red 122, 177, 254, 255, 264, 269, or 272 is preferable, C. I. Pigment Red 254, 264, or 272 is more preferable, and C. I. Pigment Red 254 or 264 is still more preferable.

Examples of the green colorant include a phthalocyanine compound and a squarylium compound, and from the reason that it is easy to form a film having more excellent long-term reliability, a phthalocyanine compound is preferable. In addition, the green colorant is preferably a pigment.

Specific examples of the green colorant include green pigments such as C. I. Pigment Green 7, 10, 36, 37, 58, 59, 62, 63, 64, 65, and 66. In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green colorant. Specific examples thereof include the compounds described in WO2015/118720A. In addition, as the green colorant, compounds described in CN2010-6909027A, phthalocyanine compounds described in WO2012/102395A, which have phosphoric acid ester as a ligand, phthalocyanine compounds described in JP2019-008014A, phthalocyanine compounds described in JP2018-180023A, compounds described in JP2019-038958A, squarylium compounds described in paragraph Nos. 0141 to 0151 of WO2019/167589A, and the like can be used.

As the green colorant, C. I. Pigment Green 7, 36, 58, 62, or 63 is preferable, and C. I. Pigment Green 36 or 58 is more preferable.

Specific examples of the orange colorant include orange pigments such as C. I. Pigment Orange 2, 5, 13, 16, 17:1, 31, 34, 36, 38, 43, 46, 48, 49, 51, 52, 55, 59, 60, 61, 62, 64, 71, and 73.

Specific examples of the violet colorant include violet pigments such as C. I. Pigment Violet 1, 19, 23, 27, 32, 37, 42, 60, and 61.

Specific examples of the blue colorant include blue pigments such as C. I. Pigment Blue 1, 2, 15, 15:1, 15:2, 15:3, 15:4, 15:6, 16, 22, 29, 60, 64, 66, 79, 80, 87, and 88.

Examples of the black colorant include a bisbenzofuranone compound, an azomethine compound, a perylene compound, and an azo compound. Among these, a bisbenzofuranone compound or a perylene compound is preferable. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF SE. Examples of the perylene compound include compounds described in paragraph Nos. 0016 to 0020 of JP2017-226821A, and C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

In a case where the coloring composition according to the embodiment of the present invention contains a green colorant, the coloring composition according to the embodiment of the present invention is preferably used as a coloring composition for forming a green pixel of a color filter. In addition, in a case where the coloring composition according to the embodiment of the present invention contains a red colorant, the coloring composition according to the embodiment of the present invention is preferably used as a coloring composition for forming a red pixel of a color filter.

In addition, the colorant contained in the coloring composition may include two or more kinds of chromatic colorants, and a combination of the two or more kinds of chromatic colorants may form black. Such a coloring composition is preferably used as a coloring composition for forming an infrared transmitting filter. In a case where the combination of two or more kinds of chromatic colorants forms black, examples of the combination of the chromatic colorants include the following.

(1): aspect in which the colorant includes a red colorant, a blue colorant, and a yellow colorant

(2): aspect in which the colorant includes a red colorant, a blue colorant, a yellow colorant, and a violet colorant

(3): aspect in which the colorant includes a red colorant, a blue colorant, a yellow colorant, a violet colorant, and a green colorant

(4): aspect in which the colorant includes a red colorant, a blue colorant, a yellow colorant, and a green colorant

(5): aspect in which the colorant includes a yellow colorant and a violet colorant

A content of the colorant in the total solid content of the coloring composition is preferably 40% by mass or more, more preferably 50% by mass or more, and still more preferably 55% by mass or more. The upper limit is preferably 80% by mass or less, more preferably 75% by mass or less, and still more preferably 70% by mass or less.

A content of the yellow colorant in the colorant is 30% by mass or more, and from the reason that a color separation from a blue pixel is improved, the content is preferably 33% by mass or more, and more preferably 35% by mass or more. The upper limit may be 100% by mass, 95% by mass or less, or 90% by mass or less.

In addition, a content of the azomethine metal complex in the yellow colorant is 15% by mass or more, preferably 15.5% by mass or more and more preferably 16% by mass or more. The upper limit may be 100% by mass, 95% by mass or less, or 90% by mass or less.

In addition, from the viewpoint of light resistance, a content of the quinophthalone compound in the yellow colorant is preferably less than 50% by mass, more preferably 40% by mass, and still more preferably 30% by mass, and it is particularly preferable that the yellow colorant does not substantially include the quinophthalone compound. In the present specification, the case where the yellow colorant does not substantially include the quinophthalone compound means that the content of the quinophthalone compound in the yellow colorant is 0.1% by mass or less, preferably 0.05% by mass or less, more preferably 0.01% by mass or less, and particularly preferably 0% by mass.

The content of the azomethine metal complex in the total solid content of the coloring composition is preferably 3% by mass or more, more preferably 5% by mass or more, and still more preferably 10% by mass or more. The upper limit is preferably 80% by mass or less, more preferably 75% by mass or less, and still more preferably 70% by mass or less.

In a case where the coloring composition according to the embodiment of the present invention is used as a coloring composition for forming a green pixel of a color filter, it is preferable to use a colorant including the yellow colorant and the green colorant. In addition, a mass ratio of the yellow colorant and the green colorant is preferably yellow colorant:green colorant=30:70 to 70:30, more preferably 30:70 to 60:40, and still more preferably 30:70 to 50:50.

In addition, the content of the azomethine metal complex is preferably 3 parts by mass or more, more preferably 5 parts by mass or more, and still more preferably 10 parts by mass or more with respect to 100 parts by mass of the green colorant.

In addition, the content of the azomethine metal complex is preferably 3 parts by mass or more, more preferably 5 parts by mass or more, and still more preferably 10 parts by mass or more with respect to 100 parts by mass of the phthalocyanine compound.

In a case where the coloring composition according to the embodiment of the present invention is used as a coloring composition for forming a red pixel of a color filter, it is preferable to use a colorant including the yellow colorant and the red colorant. In addition, a mass ratio of the yellow colorant and the red colorant is preferably yellow colorant:red colorant=30:70 to 70:30, more preferably 30:70 to 60:40, and still more preferably 30:70 to 50:50.

In addition, the content of the azomethine metal complex is preferably 3 parts by mass or more, more preferably 5 parts by mass or more, and still more preferably 10 parts by mass or more with respect to 100 parts by mass of the red colorant.

In addition, the content of the azomethine metal complex is preferably 3 parts by mass or more, more preferably 5 parts by mass or more, and still more preferably 10 parts by mass or more with respect to 100 parts by mass of the diketopyrrolopyrrole compound.

<<Resin>>

The coloring composition according to the embodiment of the present invention contains a resin. The resin is blended in, for example, an application for dispersing a pigment or the like in the coloring composition or an application as a binder. Mainly, a resin which is used for dispersing a pigment or the like in the coloring composition is also referred to as a dispersant. However, such applications of the resin are merely exemplary, and the resin can also be used for other purposes in addition to such applications.

A weight-average molecular weight (Mw) of the resin is preferably 2000 to 2000000. The upper limit is preferably 1000000 or less and more preferably 500000 or less. The lower limit is preferably 3000 or more and more preferably 5000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof.

The coloring composition according to the embodiment of the present invention preferably contains a resin having an acid group. Examples of the acid group include a carboxyl group, a phosphoric acid group, a sulfo group, and a phenolic hydroxy group. Among these acid groups, one kind may be used singly, or two or more kinds may be used in combination. The resin having an acid group can also be used as a dispersant. In a case where the coloring composition according to the embodiment of the present invention contains a resin having an acid group, a desired pattern can be formed by an alkali development. An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 200 mgKOH/g or less, still more preferably 150 mgKOH/g or less, and most preferably 120 mgKOH/g or less.

The coloring composition according to the embodiment of the present invention preferably contains a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of the basic group included in the resin having a basic group include a group represented by Formula (a-1) and a group represented by Formula (a-2).

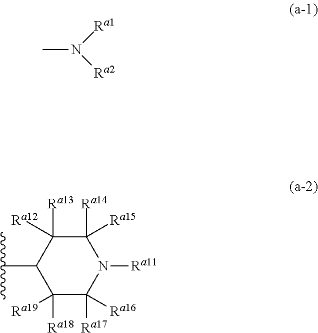

In Formula (a-1), R^{a1} and R^{a2} each independently represent a hydrogen atom, an alkyl group, or an aryl group, and R^{a1} and R^{a2} may be bonded to each other to form a ring;

in Formula (a-2), R^{a11} represents a hydrogen atom, a hydroxy group, an alkyl group, an alkoxy group, an aryl group, an aryloxy group, an acyl group, or an oxyradical, and R^{a11} to R^{a19} each independently represent a hydrogen atom, an alkyl group, or an aryl group.

The alkyl group represented by R^{a1}, R^{a2}, R^{a11} to R^{a19} preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear. The alkyl group may have a substituent.

The aryl group represented by R^{a1}, R^{a2}, R^{a11} to R^{a19} preferably has 6 to 30 carbon atoms, more preferably has 6 to 20 carbon atoms, and still more preferably has 6 to 12 carbon atoms. The aryl group may have a substituent.

The alkoxy group represented by R^{a11} preferably has 1 to 30 carbon atoms, more preferably has 1 to 15 carbon atoms, still more preferably has 1 to 8 carbon atoms, and particularly preferably has 1 to 5 carbon atoms. The alkoxy group may have a substituent.

The aryloxy group represented by R^{a11} preferably has 6 to 30 carbon atoms, more preferably has 6 to 20 carbon atoms, and still more preferably has 6 to 12 carbon atoms. The aryloxy group may have a substituent.

The acyl group represented by R^{a11} preferably has 2 to 30 carbon atoms, more preferably has 2 to 20 carbon atoms, and still more preferably has 2 to 12 carbon atoms. The acyl group may have a substituent.

Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK Chemie Japan), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF SE). In addition, as the resin having a basic group, a block copolymer (B) described in paragraph Nos. 0063 to 0112 of JP2014-219665A or a block copolymer A1 described in paragraph Nos. 0046 to 0076 of JP2018-156021A, the contents of which are incorporated herein by reference.

It is also preferable that the coloring composition according to the embodiment of the present invention contains the resin having an acid group and the resin having a basic group, respectively. According to this aspect, the storage stability of the coloring composition can be further improved. In a case where the resin having an acid group and the resin having a basic group are used in combination, a content of the resin having a basic group is preferably 20 to 500 parts by mass, more preferably 30 to 300 parts by mass, and still more preferably 50 to 200 parts by mass with respect to 100 parts by mass of the resin having an acid group.

The resin also preferably includes a resin including a repeating unit derived from a compound represented by Formula (ED1) and/or a compound represented by Formula (ED2) (hereinafter, these compounds will also be referred to as an “ether dimer”).

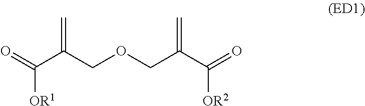

In Formula (ED1), R¹ and R² each independently represent a hydrogen atom or a hydrocarbon group having 1 to 25 carbon atoms, which may have a substituent.

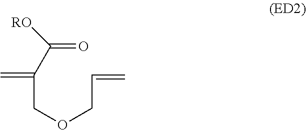

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

The resin also preferably includes a resin including a repeating unit having a polymerizable group.

The resin also preferably includes a resin including a repeating unit derived from a compound represented by Formula (X).

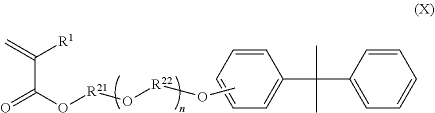

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to include a resin (hereinafter, also referred to as a resin Ac) having an aromatic carboxyl group. The resin Ac may include the aromatic carboxyl group in the main chain of the repeating unit, or in the side chain of the repeating unit. It is preferable that the aromatic carboxyl group is included in the main chain of the repeating unit. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (Ac-1) and a repeating unit represented by Formula (Ac-2).

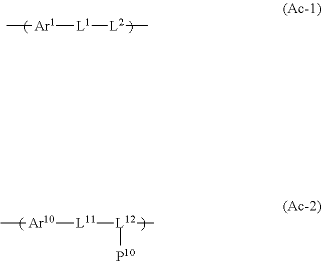

In Formula (Ac-1), Ar¹ represents a group including an aromatic carboxyl group, L¹ represents —COO— or —CONH—, and L² represents a divalent linking group.

In Formula (Ac-2), Ar¹⁰ represents a group including an aromatic carboxyl group, L¹¹ represents —COO— or —CONH—, L¹² represents a trivalent linking group, and P¹⁰ represents a polymer chain.

In Formula (Ac-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

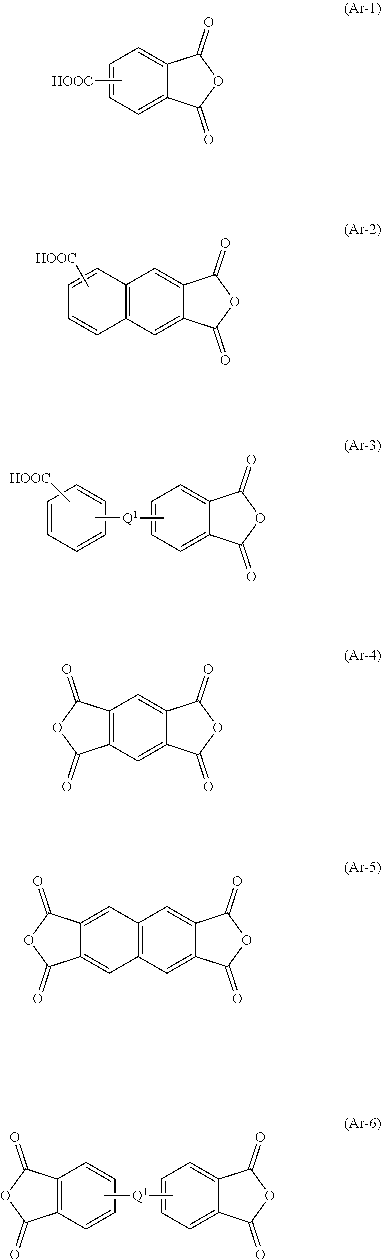

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

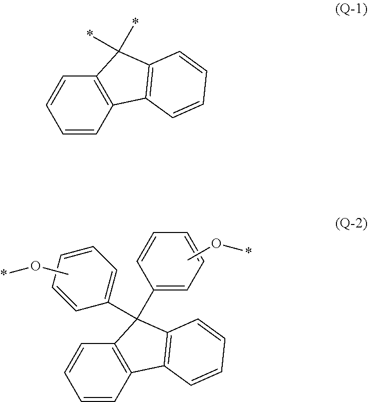

Specific examples of the group including an aromatic carboxyl group represented by Ar¹ include a group represented by Formula (Ar-11), a group represented by Formula (Ar-12), and a group represented by Formula (Ar-13).

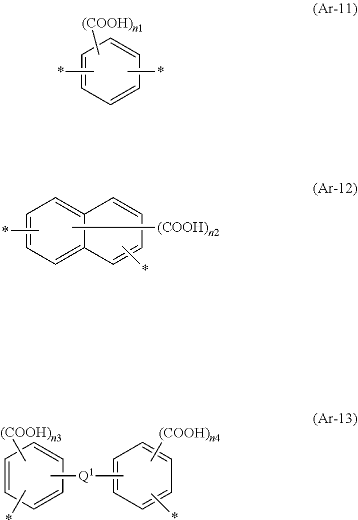

In Formula (Ar-11), n1 represents an integer of 1 to 4, and is preferably 1 or 2 and more preferably 2.

In Formula (Ar-12), n2 represents an integer of 1 to 8, and is preferably an integer of 1 or 4, more preferably 1 or 2, and still more preferably 2.

In Formula (Ar-13), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-13), Q¹ represents a single bond, —O—, —CO—, —COOCH₂CH₂OCO—, —C(CF₃)₂—, the above-described group represented by Formula (Q-1), or the above-described group represented by Formula (Q-2).

In Formula (Ac-1), L¹ represents —COO— or —CONH—, preferably —COO—.

In Formula (Ac-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by —O-L^{2a}-O—. Examples of L^{2a} include an alkylene group; an arylene group; a group formed by a combination of an alkylene group and an arylene group; and a group formed by a combination of at least one selected from an alkylene group or an arylene group, and at least one selected from —O—, —CO—, —COO—, —OCO—, —NH—, or —S—. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxyl group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxyl group is a resin having the repeating unit represented by Formula (Ac-2), this resin is preferably used as a dispersant.

The resin preferably includes a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxyl group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a resin (resin Ac) having an aromatic carboxyl group. Examples of the resin having an aromatic carboxyl group include those described above.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. The content of the repeating unit having an ethylenically unsaturated bond-containing group in the side chain is preferably 10 mol % or more, more preferably 10 to 80 mol %, and still more preferably 20 to 70 mol % with respect to the total repeating units of the resin. In addition, as the dispersant, a resin described in JP2018-087939A can also be used.

A commercially available product is also available as the dispersant, and specific examples thereof include DISPERBYK series manufactured by BYK Chemie Japan, Solsperse series manufactured by Lubrizol Japan Ltd., Efka series manufactured by BASF SE, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

In addition, as the resin used as a dispersant, block copolymers (EB-1) to (EB-9) described in paragraph Nos. 0219 to 0221 of JP6432077B can also be used.

A content of the resin in the total solid content of the coloring composition is preferably 1% to 60% by mass. The lower limit is preferably 5% by mass or more, more preferably 10% by mass or more, still more preferably 15% by mass or more, and particularly preferably 20% by mass or more. The upper limit is preferably 50% by mass or less and more preferably 40% by mass or less. The coloring composition according to the embodiment of the present invention may contain one resin or two or more kinds of resins. In a case of containing two or more kinds of resins, it is preferable that the total amount thereof is within the above-described range.

<<Solvent>>

The coloring composition according to the embodiment of the present invention contains a solvent. Examples of the solvent include an organic solvent. Basically, the type of the solvent is not particularly limited as long as it satisfies solubility of the respective components or coating properties of the composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the coloring composition is preferably 10% to 95% by mass, more preferably 20% to 90% by mass, and still more preferably 30% to 90% by mass.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, coloring composition produced by mixing these compounds, or the like.

<<Pigment Derivative>>

The coloring composition according to the embodiment of the present invention can contain a pigment derivative. Examples of the pigment derivative include a compound having a structure in which an acid group or a basic group is bonded to a coloring agent skeleton. Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

In addition, as the pigment derivative, a compound having a triazine skeleton and a structure having an acid group or a basic group can also be preferably used. Since the triazine skeleton of the pigment derivative and the pteridin skeleton of the pteridin pigment are similar, the pigment derivative is easily adsorbed on the surface of the pteridin pigment. As a result, it is presumed that a strong network is formed between the pteridin pigment, the pigment derivative, and the resin. By forming such a network, the dispersibility of the pteridin pigment in the coloring composition can be further improved, and the temporal stability of the coloring composition can be further improved. Further, it is easy to form a film in which generation of defects is suppressed. In addition, by strengthening the network between the pigment and the resin, the pigment can be easily developed together with the resin, and the developability can be further improved.

As the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol·cm⁻¹ or less, and still more preferably 100 L·mol·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later and compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

In a case of containing a pigment derivative, a content of the pigment derivative is preferably 1 to 30 parts by mass, more preferably 2 to 15 parts by mass, and still more preferably 4 to 10 parts by mass with respect to 100 parts by mass of the pigment. The pigment derivative may be used singly or in a combination of two or more kinds thereof. In a case where two or more kinds thereof are used in combination, the total amount thereof is preferably within the above-described range.

<<Infrared Absorber>>

The coloring composition according to the embodiment of the present invention may further contain an infrared absorber. For example, in a case of forming an infrared transmitting filter using the coloring composition according to the embodiment of the present invention, by containing an infrared absorber in the coloring composition, a wavelength of light transmitted through a film to be obtained can be shifted to a longer wavelength side. The infrared absorber is preferably a compound having a maximal absorption wavelength on a wavelength side longer than a wavelength of 700 nm. The infrared absorber is preferably a compound having a maximal absorption wavelength in a wavelength range of more than 700 nm and 1800 nm or less. In addition, in the infrared absorber, a ratio A¹/A², which is a ratio of an absorbance A¹ at a wavelength of 500 nm to an absorbance A² at the maximal absorption wavelength, is preferably 0.08 or less and more preferably 0.04 or less.

Examples of the infrared absorber include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B. Examples of the metal oxide include indium tin oxide, antimony tin oxide, zinc oxide, Al-doped zinc oxide, fluorine-doped tin dioxide, niobium-doped titanium dioxide, and tungsten oxide. For the details of the tungsten oxide, reference can be made to paragraph No. 0080 of JP2016-006476A, the contents of which are incorporated herein by reference. Examples of the metal boride include lanthanum boride. Examples of a commercially available product of the lanthanum boride include LaB₆-F (manufactured by Japan New Metals Co., Ltd.). In addition, compounds described in WO2017/119394A can also be used as the metal boride. Examples of a commercially available product of the indium tin oxide include F-ITO (manufactured by DOWA Hi-Tech Co., Ltd.).

In addition, as the infrared absorber, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the α-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, and the like can also be used.

In a case where the coloring composition according to the embodiment of the present invention contains an infrared absorber, a content of the infrared absorber in the total solid content of the coloring composition is preferably 1% to 40% by mass. The lower limit is preferably 2% by mass or more, more preferably 5% by mass or more, and still more preferably 10% by mass or more. The upper limit is preferably 30% by mass or less and more preferably 25% by mass or less. The coloring composition according to the embodiment of the present invention may contain one infrared absorber or two or more kinds of infrared absorbers. In a case of containing two or more kinds of infrared absorbers, it is preferable that the total amount thereof is within the above-described range.

<<Polymerizable Compound>>

The coloring composition according to the embodiment of the present invention can contain a polymerizable compound. As the polymerizable compound, a known compound which is cross-linkable by a radical, an acid, or heat can be used. In the present invention, the polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer Company Inc.) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), DPHA-40H (manufactured by Nippon Kayaku Co., Ltd.), UA-306H, UA-306T, UA-3061, AH-600, T-600, AI-600, and LINC-202UA (manufactured by KYOEISHA CHEMICAL Co., LTD.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable compound, a compound having an acid group can also be used. By using a polymerizable compound having an acid group, the polymerizable compound in a non-exposed portion is easily removed during development and the generation of a development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

In addition, as the polymerizable compound, a compound having a caprolactone structure can also be used. Examples of a commercially available product of the polymerizable compound having a caprolactone structure include KAYARAD DPCA-20, DPCA-30, DPCA-60, and DPCA-120 (all manufactured by Nippon Kayaku Co., Ltd.).

In addition, as the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of the polymerizable compound having an alkyleneoxy group include compounds having the following structures. Examples of a commercially available product of the polymerizable compound having an alkyleneoxy group include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

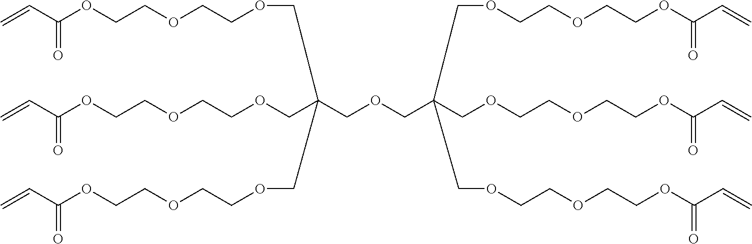 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

In addition, as the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

A content of the polymerizable compound in the total solid content of the coloring composition is preferably 0.1% to 50% by mass. The lower limit is more preferably 0.5% by mass or more and still more preferably 1% by mass or more. The upper limit is more preferably 45% by mass or less and still more preferably 40% by mass or less. The polymerizable compound may be used singly or in a combination of two or more kinds thereof. In a case where two or more kinds thereof are used in combination, the total thereof is preferably within the above-described range.

<<Photopolymerization Initiator>>

The coloring composition according to the embodiment of the present invention can contain a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF SE), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

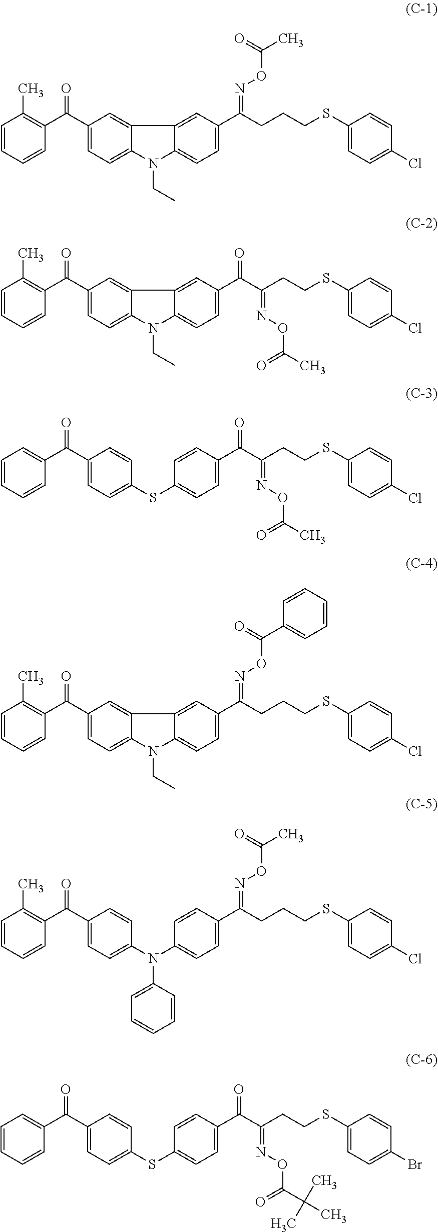 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

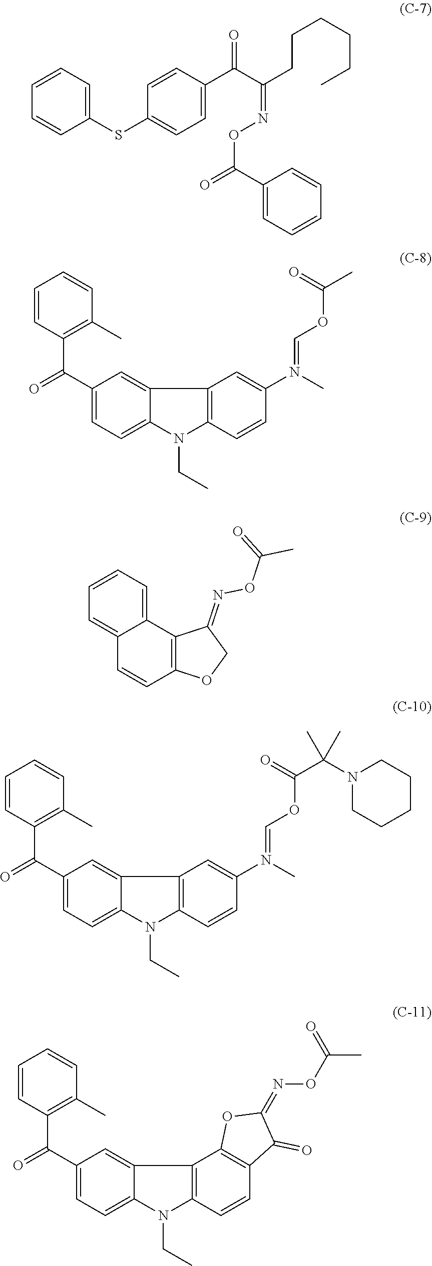

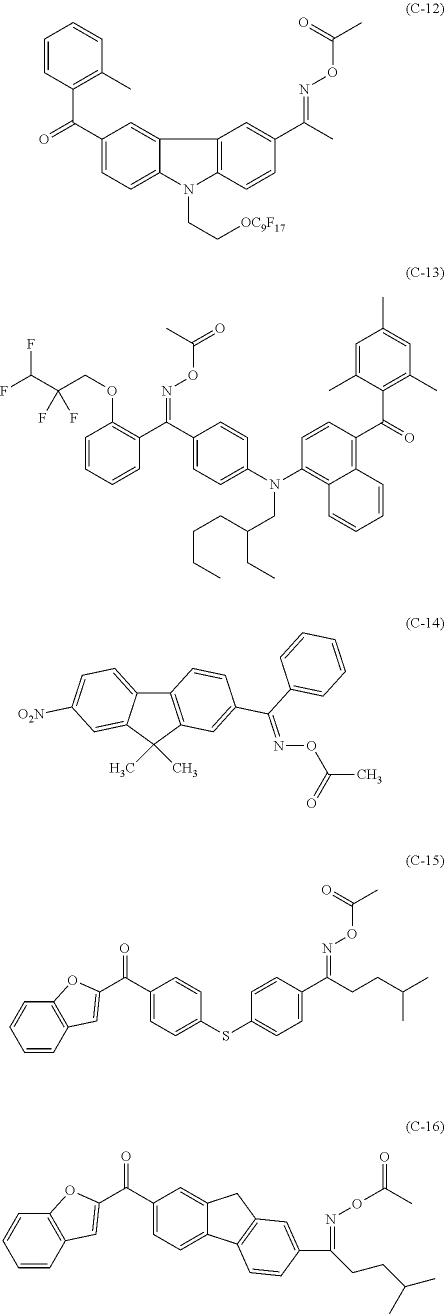

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian Medical Systems, Inc.) using an ethyl acetate solvent at a concentration of 0.01 g/L.

As the photopolymerization initiator, it is also preferable to use Irgacure OXE01 (manufactured by BASF SE) and/or Irgacure OXE02 (manufactured by BASF SE) and Omnirad 2959 (manufactured by IGM Resins B.V.) in combination.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

In a case of containing a photopolymerization initiator, a content of the photopolymerization initiator in the total solid content of the coloring composition is preferably 0.1% to 30% by mass. The lower limit is preferably 0.5% by mass or more and more preferably 1% by mass or more. The upper limit is preferably 20% by mass or less and more preferably 15% by mass or less. In the coloring composition according to the embodiment of the present invention, the photopolymerization initiator may be used singly or in a combination of two or more kinds thereof. In a case where two or more kinds thereof are used, the total amount thereof is preferably within the above-described range.

<<Compound Having Cyclic Ether Group>>

The coloring composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

As the epoxy compound, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

A content of the compound having a cyclic ether group in the total solid content of the coloring composition is preferably 0.1% to 20% by mass. The lower limit is, for example, preferably 0.5% by mass or more and more preferably 1% by mass or more. The upper limit is, for example, preferably 15% by mass or less and still more preferably 10% by mass or less. The compound having a cyclic ether group may be used singly or in a combination of two or more kinds thereof. In a case of using two or more kinds thereof, the total amount thereof is preferably within the above-described range.

<<Curing Accelerator>>

The coloring composition according to the embodiment of the present invention may contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 0080 of JP2012-150180A, alkoxysilane compounds having an epoxy group described in JP2011-253054A, compounds described in paragraph Nos. 0085 to 0092 of JP5765059B, and carboxyl group-containing epoxy curing agent described in JP2017-036379A. In a case of containing a curing accelerator, a content of the curing accelerator in the total solid content of the coloring composition is preferably 0.3% to 8.9% by mass and more preferably 0.8% to 6.4% by mass.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used.

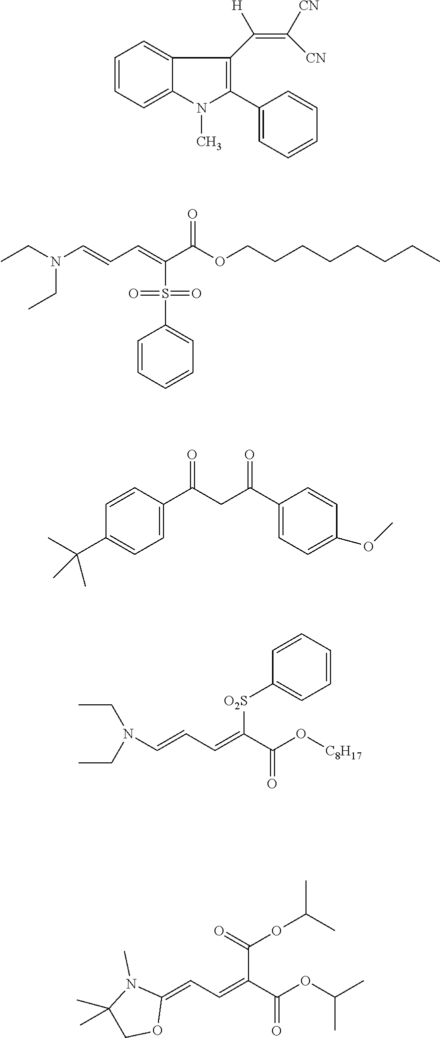

In a case of containing an ultraviolet absorber, a content of the ultraviolet absorber in the total solid content of the coloring composition is preferably 0.01% to 10% by mass and more preferably 0.01% to 5% by mass. In the present invention, the ultraviolet absorber may be used singly or in a combination of two or more kinds thereof. In a case of using two or more kinds thereof, the total amount thereof is preferably within the above-described range.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. In a case of containing a polymerization inhibitor, a content of the polymerization inhibitor in the total solid content of the coloring composition is preferably 0.0001% to 5% by mass. The polymerization inhibitor may be used singly or in a combination of two or more kinds thereof. In a case of two or more kinds thereof, the total amount thereof is preferably within the above-described range.

<<Silane Coupling Agent>>

The coloring composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference. In a case of containing a silane coupling agent, a content of the silane coupling agent in the total solid content of the coloring composition is preferably 0.01% to 15.0% by mass and more preferably 0.05% to 10.0% by mass. The silane coupling agent may be used singly or in a combination of two or more kinds thereof. In a case of two or more kinds thereof, the total amount thereof is preferably within the above-described range.

<<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

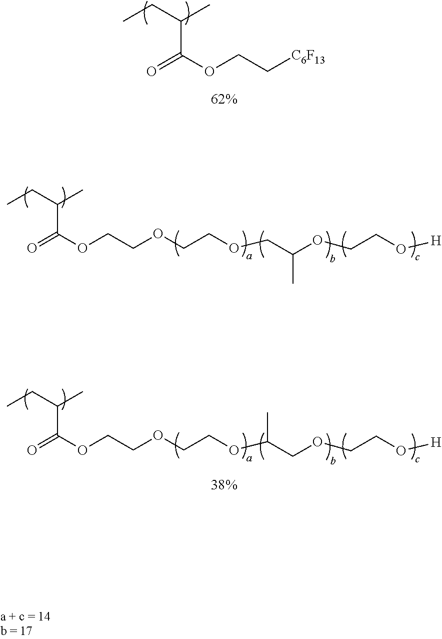

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Silicone Co., Ltd.), and BYK307, BYK323, and BYK330 (all of which are manufactured by BYK Chemie).

In a case of containing a surfactant, a content of the surfactant in the total solid content of the coloring composition is preferably 0.001% to 5.0% by mass and more preferably 0.005% to 3.0% by mass. The surfactant may be used singly or in a combination of two or more kinds thereof. In a case of two or more kinds thereof, the total amount thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. A content of the antioxidant in the total solid content of the coloring composition is preferably 0.01% to 20% by mass and more preferably 0.3% to 15% by mass. In a case of containing the antioxidant, the antioxidant may be used singly or in a combination of two or more kinds thereof. In a case of using two or more kinds thereof, the total amount thereof is preferably within the above-described range.

<<Other Components>>

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of a film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The coloring composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

The moisture content in the coloring composition according to the embodiment of the present invention is usually 3% by mass or less, preferably 0.01% to 1.5% by mass and more preferably in a range of 0.1% to 1.0% by mass. The moisture content can be measured by a Karl Fischer method.

The coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a cone plate-type viscometer.

A storage container of the coloring composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A.

<Method of Preparing Coloring Composition>

The coloring composition according to the embodiment of the present invention can be prepared by mixing the above-described components with each other. In the preparation of the coloring composition, all the components may be dissolved and/or dispersed at the same time in a solvent to prepare the coloring composition, or the respective components may be appropriately left in two or more solutions or dispersion liquids and mixed to prepare the coloring composition upon use (during coating), as desired.

In addition, in the preparation of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described coloring composition according to the embodiment of the present invention. The film according to the embodiment of the present invention can be used for an optical filter such as a color filter or an infrared transmitting filter.

A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

In a case where the film according to the embodiment of the present invention is used as a color filter, the film according to the embodiment of the present invention preferably has a hue of green, red, blue, cyan, magenta, or yellow, and more preferably has a hue of green, red, or yellow. In addition, the film according to the embodiment of the present invention can be preferably used as a colored pixel of a color filter. Examples of the colored pixel include a red pixel, a green pixel, a blue pixel, a magenta pixel, a cyan pixel, and a yellow pixel, and a red pixel, a green pixel, or a yellow pixel is preferable, a red pixel or a green pixel is more preferable, and a green pixel is still more preferable.

In addition, in the film according to the embodiment of the present invention, a wavelength at which a light transmittance is 50% preferably exists in a wavelength range of 470 to 520 nm, more preferably exists in a wavelength range of 475 to 520 nm, and still more preferably exists in a wavelength range of 480 to 520 nm. Among these, the wavelength at which the light transmittance is 50% preferably exists in each wavelength range of 470 to 520 nm and wavelength range of 575 to 625 nm. In this aspect, a wavelength on a short wavelength side, at which the light transmittance is 50%, preferably exists in a wavelength range of 475 to 520 nm, and more preferably exists in a wavelength range of 480 to 520 nm. In addition, a wavelength on a long wavelength side, at which the light transmittance is 50%, preferably exists in a wavelength range of 580 to 620 nm, and more preferably exists in a wavelength range of 585 to 615 nm. A film having such spectral characteristics is preferably used as a green pixel.

In a case where the film according to the embodiment of the present invention is used as an infrared transmitting filter, it is preferable that the film according to the embodiment of the present invention has, for example, any one of the following spectral characteristics (1) to (4).

(1): maximum value of a light transmittance of the film in a thickness direction in a wavelength range of 400 to 640 nm is 20% or less (preferably 15% or less and more preferably 10% or less) and the minimum value of a light transmittance of the film in the thickness direction in a wavelength range of 800 to 1300 nm is 70% or more (preferably 75% or more and more preferably 80% or more). A film having such spectral characteristics can shield light having a wavelength range of 400 to 640 nm, and can transmit light having a wavelength exceeding 700 nm.

(2): film in which the maximum value of a light transmittance of the film in a thickness direction in a wavelength range of 400 to 750 nm is 20% or less (preferably 15% or less and more preferably 10% or less) and the minimum value of a light transmittance of the film in the thickness direction in a wavelength range of 900 to 1300 nm is 70% or more (preferably 75% or more and more preferably 80% or more). A film having such spectral characteristics can shield light having a wavelength range of 400 to 750 nm, and can transmit light having a wavelength exceeding 850 nm.

(3): film in which the maximum value of a light transmittance of the film in a thickness direction in a wavelength range of 400 to 830 nm is 20% or less (preferably 15% or less and more preferably 10% or less) and the minimum value of a light transmittance of the film in the thickness direction in a wavelength range of 1000 to 1300 nm is 70% or more (preferably 75% or more and more preferably 80% or more). A film having such spectral characteristics can shield light having a wavelength range of 400 to 830 nm, and can transmit light having a wavelength exceeding 940 nm.

(4): film in which the maximum value of a light transmittance of the film in a thickness direction in a wavelength range of 400 to 950 nm is 20% or less (preferably 15% or less and more preferably 10% or less) and the minimum value of a light transmittance of the film in the thickness direction in a wavelength range of 1100 to 1300 nm is 70% or more (preferably 75% or more and more preferably 80% or more). A film having such spectral characteristics can shield light having a wavelength range of 400 to 950 nm, and can transmit light having a wavelength exceeding 1040 nm.

<Method for Producing Film>

Next, a method for producing the film according to the embodiment of the present invention will be described. The film according to the embodiment of the present invention can be formed through a step of applying the coloring composition according to the embodiment of the present invention. The method for producing the film preferably further includes a step of forming a pattern (pixel). Examples of a method for forming the pattern (pixel) include a photolithography method and a dry etching method, and a photolithography method is preferable.

Pattern formation by a photolithography method preferably includes a step of forming a coloring composition layer on a support using the coloring composition according to the embodiment of the present invention, a step of exposing the coloring composition layer in a patterned manner, and a step of removing a non-exposed portion of the coloring composition layer by development to form a pattern (pixel). A step (pre-baking step) of baking the coloring composition layer and a step (post-baking step) of baking the developed pattern (pixel) may be provided, optionally.

In the step of forming a coloring composition layer, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. The base layer may be formed of a composition obtained by removing a colorant from the coloring composition described in the present specification, a composition including the curable compound, surfactant, and the like described in the present specification, or the like. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the resin composition is good. The surface contact angle of the base layer can be adjusted by, for example, adding a surfactant.

As a method of applying the coloring composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

<Optical Filter>

An optical filter according to an embodiment of the present invention has the above-described film according to the embodiment of the present invention. Examples of the type of the optical filter include a color filter and an infrared transmitting filter, and a color filter is preferable. As the color filter, it is preferable to have the film according to the embodiment of the present invention as a colored pixel of the color filter.

In the optical filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si2N4, and two or more kinds of these components may be contained. For example, in a case of a protective layer for oxygen shielding, it is preferable that the protective layer contains a polyol resin, SiO₂, and Si2N4. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The optical filter may have a structure in which each pixel is embedded in a space partitioned in, for example, a lattice form by a partition wall.

<Solid-State Imaging Element>

A solid-state imaging element according to an embodiment of the present invention has the film according to the embodiment of the present invention. The configuration of the solid-state imaging element is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. The partition wall in this case preferably has a low refractive index for each colored pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Production of Dispersion Liquid>

A mixed solution obtained by mixing raw materials shown in the following tables was mixed and dispersed for 3 hours using a beads mill (zirconia beads having a diameter of 0.1 mm). Next, using a high-pressure disperser NANO-3000-10 (manufactured by Nippon BEE Chemical Co., Ltd.) equipped with a pressure reducing mechanism, the dispersion liquid was dispersed under a pressure of 2000 kg/cm′ at a flow rate of 500 g/min. The dispersion treatment was repeated a total of 10 times to obtain a dispersion liquid. The numerical values indicating the blending amount shown in the following tables indicate parts by mass. The following tables also show the content (yellow colorant ratio in the tables) of the yellow colorant in the colorant and the content (azomethine metal complex ratio in the tables) of the azomethine metal complex in the yellow colorant.

TABLE 1

| | | Dispersion | Dispersion | Dispersion | Dispersion | Dispersion | Dispersion | Dispersion | Dispersion |
|---|---|---|---|---|---|---|---|---|---|
| | | liquid 1 | liquid 2 | liquid 3 | liquid 4 | liquid 5 | liquid 6 | liquid 7 | liquid 8 |
| Green colorant | PG58 | 8.5 | 7.9 | 7.2 | 6.7 | | | | |
| | PG36 | | | | | 8.5 | 7.9 | 7.2 | 6.7 |
| | PG62 | | | | | | | | |
| Red colorant | PR254 | | | | | | | | |
| | PR264 | | | | | | | | |
| | PR272 | | | | | | | | |
| Yellow | Azomethine metal | 1.1 | 2.2 | 2.9 | 3.7 | 1.1 | 2.2 | 2.9 | 3.7 |
| colorant | complex 1 | | | | | | | | |
| | Azomethine metal | | | | | | | | |
| | complex 2 | | | | | | | | |
| | Azomethine metal | | | | | | | | |
| | complex 3 | | | | | | | | |
| | PY139 | 3.0 | 2.5 | 2.5 | 2.2 | 3.0 | 2.5 | 2.5 | 2.2 |
| | PY150 | | | | | | | | |
| | PY215 | | | | | | | | |
| | PY185 | | | | | | | | |
| | PY138 | | | | | | | | |
| Pigment | Pigment derivative 1 | 1.4 | 1.4 | 1.4 | 1.4 | 1.4 | 1.4 | 1.4 | 1.4 |
| derivative | | | | | | | | | |
| Dispersant | B-1 | 16.7 | 16.7 | 16.7 | 16.7 | 16.7 | 16.7 | 16.7 | 16.7 |
| | B-2 | | | | | | | | |
| | B-3 | | | | | | | | |
| Solvent | Solvent 1 | 69.3 | 69.3 | 69.3 | 69.3 | 69.3 | 69.3 | 69.3 | 69.3 |

| | | | | | | | | |
|---|---|---|---|---|---|---|---|---|
| Yellow colorant ratio | 33% | 37% | 43% | 47% | 33% | 37% | 43% | 47% |
| Azomethine metal complex ratio | 27% | 47% | 54% | 63% | 27% | 47% | 54% | 63% |

TABLE 2

| | | Dispersion | Dispersion | Dispersion | Dispersion | Dispersion | Dispersion | Dispersion | Dispersion |
|---|---|---|---|---|---|---|---|---|---|
| | | liquid 9 | liquid 10 | liquid 11 | liquid 12 | liquid 13 | liquid 14 | liquid 15 | liquid 16 |
| Green colorant | PG58 | 8.5 | 7.9 | 7.2 | 6.7 | | | | |
| | PG36 | | | | | 8.5 | 7.9 | 7.2 | 6.7 |
| | PG62 | | | | | | | | |
| Red colorant | PR254 | | | | | | | | |
| | PR264 | | | | | | | | |
| | PR272 | | | | | | | | |
| Yellow | Azomethine metal | 1.1 | 2.2 | 2.9 | 3.7 | 1.1 | 2.2 | 2.9 | 3.7 |
| colorant | complex 1 | | | | | | | | |
| | Azomethine metal | | | | | | | | |
| | complex 2 | | | | | | | | |
| | Azomethine metal | | | | | | | | |
| | complex 3 | | | | | | | | |
| | PY139 | | | | | | | | |
| | PY150 | 3.0 | 2.5 | 2.5 | 2.2 | 3.0 | 2.5 | 2.5 | 2.2 |
| | PY215 | | | | | | | | |
| | PY185 | | | | | | | | |
| | PY138 | | | | | | | | |
| Pigment | Pigment derivative 1 | 1.4 | 1.4 | 1.4 | 1.4 | 1.4 | 1.4 | 1.4 | 1.4 |
| derivative | | | | | | | | | |
| Dispersant | B-1 | 16.7 | 16.7 | 16.7 | 16.7 | 16.7 | 16.7 | 16.7 | 16.7 |
| | B-2 | | | | | | | | |
| | B-3 | | | | | | | | |
| Solvent | Solvent 1 | 69.3 | 69.3 | 69.3 | 69.3 | 69.3 | 69.3 | 69.3 | 69.3 |

| | | | | | | | | |
|---|---|---|---|---|---|---|---|---|
| Yellow colorant ratio | 33% | 37% | 43% | 47% | 33% | 37% | 43% | 47% |
| Azomethine metal complex ratio | 27% | 47% | 54% | 63% | 27% | 47% | 54% | 63% |

TABLE 3

| | | Dispersion | Dispersion | Dispersion | Dispersion | Dispersion | Dispersion | Dispersion | Dispersion |
|---|---|---|---|---|---|---|---|---|---|
| | | liquid 17 | liquid 18 | liquid 19 | liquid 20 | liquid 21 | liquid 22 | liquid 23 | liquid 24 |
| Green colorant | PG58 | | | | | | | | |
| | PG36 | 7.7 | 7.9 | 8.1 | 8.3 | 7.7 | 7.9 | 8.1 | 8.3 |
| | PG62 | | | | | | | | |
| Red colorant | PR254 | | | | | | | | |
| | PR264 | | | | | | | | |
| | PR272 | | | | | | | | |
| Yellow | Azomethine metal | 2.3 | 2.5 | 1.9 | 1.4 | 2.3 | 2.5 | 1.9 | 1.4 |
| colorant | complex 1 | | | | | | | | |
| | Azomethine metal | | | | | | | | |
| | complex 2 | | | | | | | | |
| | Azomethine metal | | | | | | | | |
| | complex 3 | | | | | | | | |
| | PY139 | | | | | | | | |
| | PY150 | | | | | 2.5 | 1.9 | 1.9 | 1.6 |
| | PY215 | 2.5 | 1.9 | 1.9 | 1.6 | | | | |
| | PY185 | | 0.4 | 0.8 | 1.4 | | 0.4 | 0.8 | 1.4 |
| | PY138 | | | | | | | | |
| Pigment | Pigment derivative 1 | 1.4 | 1.4 | 1.4 | 1.4 | 1.4 | 1.4 | 1.4 | 1.4 |
| derivative | | | | | | | | | |
| Dispersant | B-1 | 16.7 | 16.7 | 16.7 | 16.7 | 16.7 | 16.7 | 16.7 | 16.7 |
| | B-2 | | | | | | | | |
| | B-3 | | | | | | | | |
| Solvent | Solvent 1 | 69.3 | 69.3 | 69.3 | 69.3 | 69.3 | 69.3 | 69.3 | 69.3 |

| | | | | | | | | |
|---|---|---|---|---|---|---|---|---|
| Yellow colorant ratio | 39% | 37% | 36% | 34% | 39% | 37% | 36% | 34% |
| Azomethine metal complex ratio | 48% | 52% | 41% | 32% | 48% | 52% | 41% | 32% |

TABLE 4

| | | Dispersion | Dispersion | Dispersion | Dispersion | Dispersion | Dispersion | Dispersion | Dispersion |
|---|---|---|---|---|---|---|---|---|---|
| | | liquid 25 | liquid 26 | liquid 27 | liquid 28 | liquid 29 | liquid 30 | liquid 31 | liquid 32 |
| Green colorant | PG58 | 7.9 | 7.9 | 7.9 | | | | | 8.5 |
| | PG36 | | | | | | | | |
| | PG62 | | | | 7.9 | | | | |
| Red colorant | PR254 | | | | | 8.5 | | | |
| | PR264 | | | | | | 8.5 | | |
| | PR272 | | | | | | | 8.5 | |
| Yellow | Azomethine metal | | | 1.1 | 2.2 | 4.1 | 4.1 | 4.1 | 2.5 |
| colorant | complex 1 | | | | | | | | |
| | Azomethine metal | 2.2 | | 1.1 | | | | | |
| | complex 2 | | | | | | | | |
| | Azomethine metal | | 2.2 | | | | | | |
| | complex 3 | | | | | | | | |
| | PY139 | 2.5 | 2.5 | 2.5 | 2.5 | | | | |
| | PY150 | | | | | | | | |
| | PY215 | | | | | | | | |
| | PY185 | | | | | | | | |
| | PY138 | | | | | | | | 1.6 |
| Pigment | Pigment derivative 1 | 1.4 | 1.4 | 1.4 | 1.4 | 1.4 | 1.4 | 1.4 | 1.4 |
| derivative | | | | | | | | | |
| Dispersant | B-1 | 16.7 | 16.7 | 16.7 | 16.7 | 16.7 | 16.7 | 16.7 | 16.7 |
| | B-2 | | | | | | | | |
| | B-3 | | | | | | | | |
| Solvent | Solvent 1 | 69.3 | 69.3 | 69.3 | 69.3 | 69.3 | 69.3 | 69.3 | 69.3 |

| | | | | | | | | |
|---|---|---|---|---|---|---|---|---|
| Yellow colorant ratio | 37% | 37% | 37% | 37% | 33% | 33% | 33% | 33% |
| Azomethine metal complex ratio | 47% | 47% | 47% | 47% | 100% | 100% | 100% | 60% |

TABLE 5

| | | Dispersion | Dispersion | Dispersion | Dispersion |
|---|---|---|---|---|---|
| | | liquid | liquid | liquid | liquid |
| | | 33 | 34 | 35 | c1 |
| Green colorant | PG58 | 7.9 | 7.9 | 8.5 | |
| | PG36 | | | | 9.1 |
| | PG62 | | | | |
| Red colorant | PR254 | | | | |
| | PR264 | | | | |
| | PR272 | | | | |
| Yellow colorant | Azomethine metal complex 1 | 2.2 | 2.2 | 1.2 | 0.5 |
| | Azomethine metal complex 2 | | | | |
| | Azomethine metal complex 3 | | | | |
| | PY139 | 2.5 | 2.5 | | 3.0 |
| | PY150 | | | | |
| | PY215 | | | | |
| | PY185 | | | | |
| | PY138 | | | 2.9 | |
| Pigment derivative | Pigment derivative 1 | | | 1.4 | 1.4 |
| Dispersant | B-1 | | | 16.7 | 16.7 |
| | B-2 | 16.7 | | | |
| | B-3 | | 16.7 | | |
| Solvent | Solvent 1 | 69.3 | 69.3 | 69.3 | 69.3 |

| | | | | |
|---|---|---|---|---|
| Yellow colorant ratio | 37% | 37% | 33% | 28% |
| Azomethine metal complex ratio | 47% | 47% | 30% | 14% |

The raw materials described by abbreviations shown in the above tables are as follows.

(Green Colorant)
PG36: C. I. Pigment Green 36 (phthalocyanine compound, green pigment)
PG58: C. I. Pigment Green 58 (phthalocyanine compound, green pigment)
PG62: C. I. Pigment Green 62 (phthalocyanine compound, green pigment)

(Red Colorant)
PR254: C. I. Pigment Red 254 (diketopyrrolopyrrole compound, red pigment)
PR264: C. I. Pigment Red 264 (diketopyrrolopyrrole compound, red pigment)
PR272: C. I. Pigment Red 272 (diketopyrrolopyrrole compound, red pigment)

(Yellow Colorant)

Azomethine metal complex 1: C. I. Pigment Yellow 129 (azomethine copper complex, compound having the following structure, yellow pigment)

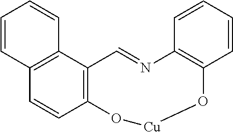

Azomethine metal complex 2

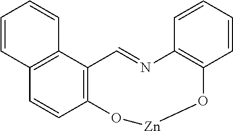

Azomethine metal complex 3

1:1 solid solution of the azomethine metal complex 1 (C. I. Pigment Yellow 129) and the azomethine metal complex 2
PY138: C. I. Pigment Yellow 138 (quinophthalone compound, yellow pigment)
PY139: C. I. Pigment Yellow 139 (isoindoline compound, yellow pigment)
PY150: C. I. Pigment Yellow 150 (azo compound, yellow pigment)
PY185: C. I. Pigment Yellow 185 (isoindoline compound, yellow pigment)
PY215: C. I. Pigment Yellow 215 (pteridin compound, yellow pigment)

(Pigment Derivative)

Pigment derivative 1: compound having the following structure

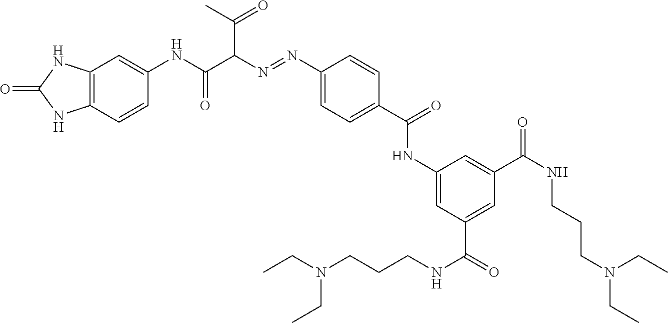 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

(Dispersant)

B-1: resin having the following structure (propylene glycol monomethyl ether acetate (PGMEA) solution having a concentration of solid contents of 30% by mass; the numerical value described together with the main chain indicates a mass ratio, and the numerical value described together with the side chain indicates the number of repeating units; weight-average molecular weight=13000, acid value: 65 mgKOH/g)

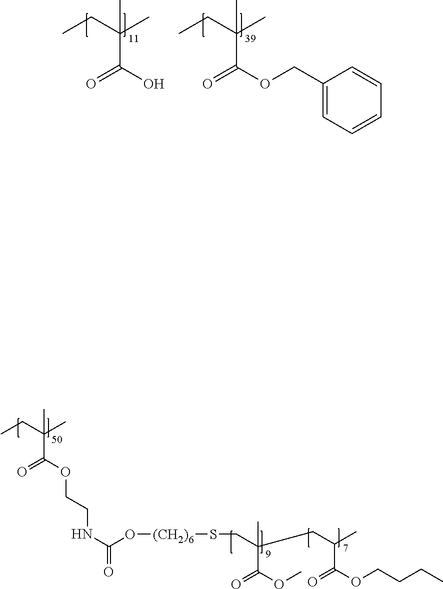

B-2: resin solution of a resin B-2 synthesized by the following method (PGMEA solution having a concentration of solid contents of 30% by mass) 50 parts by mass of methyl methacrylate, 30 parts by mass of n-butyl methacrylate, 20 parts by mass of t-butyl methacrylate, and 45.4 parts by mass of PGMEA were charged into a reaction container, and the atmosphere gas was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 30% by mass, thereby obtaining a resin solution of a resin B-2 having the following structure, in which an acid value was 43 mgKOH/g and a weight-average molecular weight was 9000.

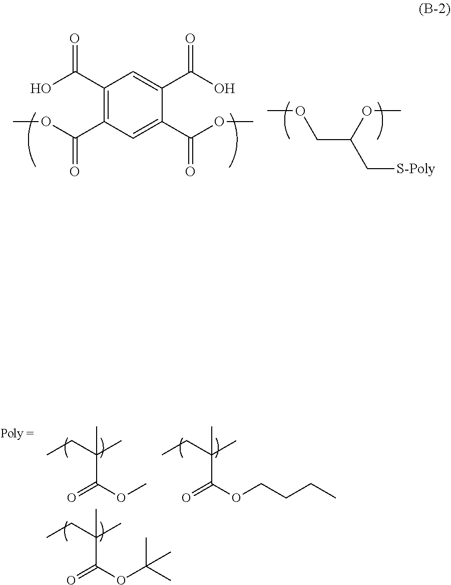

B-3: resin solution of a resin B-3 synthesized by the following method (PGMEA solution having a concentration of solid contents of 30% by mass)

A resin solution of a resin B-3 having the following structure, in which an acid value was 43 mgKOH/g and a weight-average molecular weight was 9000, was obtained in the same manner as in the synthesis of the resin B-2, except that 20 parts by mass of t-butyl methacrylate was changed to (3-ethyloxetan-3-yl)methyl methacrylate.

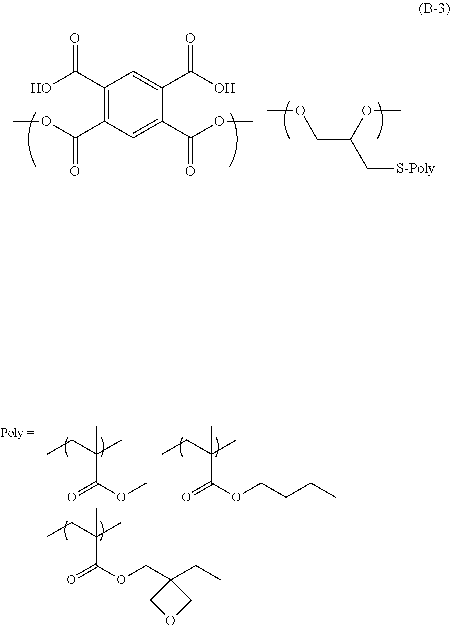

(Solvent)

Solvent 1: propylene glycol monomethyl ether acetate (PGMEA)

<Production of Coloring Composition>

Raw materials described in the following tables were mixed to produce a coloring composition.

TABLE 6

| | Example | Example | Example | Example | Example | Example | Example | Example |
|---|---|---|---|---|---|---|---|---|
| | 1 | 2 | 3 | 4 | 5 | 6 | 7 | 8 |
| Dispersion liquid 1 | 78.2 | | | | | | | |
| Dispersion liquid 2 | | 85.0 | | | | | | |
| Dispersion liquid 3 | | | 87.7 | | | | | |
| Dispersion liquid 4 | | | | 90.4 | | | | |
| Dispersion liquid 5 | | | | | 78.2 | | | |
| Dispersion liquid 6 | | | | | | 85.0 | | |
| Dispersion liquid 7 | | | | | | | 87.7 | |
| Dispersion liquid 8 | | | | | | | | 90.4 |
| Dispersion liquid 9 | | | | | | | | |
| Dispersion liquid 10 | | | | | | | | |
| Dispersion liquid 11 | | | | | | | | |
| Dispersion liquid 12 | | | | | | | | |
| Dispersion liquid 13 | | | | | | | | |
| Dispersion liquid 14 | | | | | | | | |
| Dispersion liquid 15 | | | | | | | | |
| Dispersion liquid 16 | | | | | | | | |
| Dispersion liquid 17 | | | | | | | | |
| Dispersion liquid 18 | | | | | | | | |
| Dispersion liquid 19 | | | | | | | | |
| Dispersion liquid 20 | | | | | | | | |
| Dispersion liquid 21 | | | | | | | | |
| Dispersion liquid 22 | | | | | | | | |
| Dispersion liquid 23 | | | | | | | | |
| Dispersion liquid 24 | | | | | | | | |
| Dispersion liquid 25 | | | | | | | | |
| Dispersion liquid 26 | | | | | | | | |
| Dispersion liquid 27 | | | | | | | | |
| Dispersion liquid 28 | | | | | | | | |
| Dispersion liquid 29 | | | | | | | | |
| Dispersion liquid 30 | | | | | | | | |
| Dispersion liquid 31 | | | | | | | | |
| Dispersion liquid 32 | | | | | | | | |
| Dispersion liquid 33 | | | | | | | | |
| Dispersion liquid 34 | | | | | | | | |
| Dispersion liquid 35 | | | | | | | | |
| Dispersion liquid c1 | | | | | | | | |
| Resin 1 | 0.3 | 0.2 | 0.2 | 0.3 | 0.3 | 0.2 | 0.2 | 0.3 |
| Resin 2 | | | | | | | | |
| Polymerizable | 2.5 | 1.5 | 1.1 | 0.7 | 2.5 | 1.5 | 1.1 | 0.7 |
| compound 1 | | | | | | | | |
| Polymerizable | | | | | | | | |
| compound 2 | | | | | | | | |
| Photopolymerization | 0.8 | 0.5 | 0.4 | 0.2 | 0.8 | 0.5 | 0.4 | 0.2 |
| initiator 1 | | | | | | | | |
| Photopolymerization | | | | | | | | |
| initiator 2 | | | | | | | | |
| Photopolymerization | | | | | | | | |
| initiator 3 | | | | | | | | |
| Surfactant 1 | 4.2 | 4.2 | 4.2 | 4.2 | 4.2 | 4.2 | 4.2 | 4.2 |
| Silane coupling agent | 0.4 | 0.4 | 0.4 | 0.4 | 0.4 | 0.4 | 0.4 | 0.4 |
| 1 | | | | | | | | |
| Epoxy compound 1 | 0.4 | 0.4 | 0.4 | 0.4 | 0.4 | 0.4 | 0.4 | 0.4 |
| Solvent 1 | 13.3 | 7.9 | 5.7 | 3.4 | 13.3 | 7.9 | 5.7 | 3.4 |
| Solvent 2 | | | | | | | | |

TABLE 7

| | Example | Example | Example | Example | Example | Example | Example | Example |
|---|---|---|---|---|---|---|---|---|
| | 9 | 10 | 11 | 12 | 13 | 14 | 15 | 16 |
| Dispersion liquid 1 | | | | | | | | |
| Dispersion liquid 2 | | | | | | | | |
| Dispersion liquid 3 | | | | | | | | |
| Dispersion liquid 4 | | | | | | | | |
| Dispersion liquid 5 | | | | | | | | |
| Dispersion liquid 6 | | | | | | | | |
| Dispersion liquid 7 | | | | | | | | |
| Dispersion liquid 8 | | | | | | | | |
| Dispersion liquid 9 | 78.2 | | | | | | | |
| Dispersion liquid 10 | | 85.0 | | | | | | |
| Dispersion liquid 11 | | | 87.7 | | | | | |
| Dispersion liquid 12 | | | | 90.4 | | | | |
| Dispersion liquid 13 | | | | | 78.2 | | | |
| Dispersion liquid 14 | | | | | | 85.0 | | |
| Dispersion liquid 15 | | | | | | | 87.7 | |
| Dispersion liquid 16 | | | | | | | | 90.4 |
| Dispersion liquid 17 | | | | | | | | |
| Dispersion liquid 18 | | | | | | | | |
| Dispersion liquid 19 | | | | | | | | |
| Dispersion liquid 20 | | | | | | | | |
| Dispersion liquid 21 | | | | | | | | |
| Dispersion liquid 22 | | | | | | | | |
| Dispersion liquid 23 | | | | | | | | |
| Dispersion liquid 24 | | | | | | | | |
| Dispersion liquid 25 | | | | | | | | |
| Dispersion liquid 26 | | | | | | | | |
| Dispersion liquid 27 | | | | | | | | |
| Dispersion liquid 28 | | | | | | | | |
| Dispersion liquid 29 | | | | | | | | |
| Dispersion liquid 30 | | | | | | | | |
| Dispersion liquid 31 | | | | | | | | |
| Dispersion liquid 32 | | | | | | | | |
| Dispersion liquid 33 | | | | | | | | |
| Dispersion liquid 34 | | | | | | | | |
| Dispersion liquid 35 | | | | | | | | |
| Dispersion liquid c1 | | | | | | | | |
| Resin 1 | 0.3 | 0.2 | 0.2 | 0.3 | 0.3 | 0.2 | 0.2 | 0.3 |
| Resin 2 | | | | | | | | |
| Polymerizable | 2.5 | 1.5 | 1.1 | 0.7 | 2.5 | 1.5 | 1.1 | 0.7 |
| compound 1 | | | | | | | | |
| Polymerizable | | | | | | | | |
| compound 2 | | | | | | | | |
| Photopolymerization | 0.8 | 0.5 | 0.4 | 0.2 | 0.8 | 0.5 | 0.4 | 0.2 |
| initiator 1 | | | | | | | | |
| Photopolymerization | | | | | | | | |
| initiator 2 | | | | | | | | |
| Photopolymerization | | | | | | | | |
| initiator 3 | | | | | | | | |
| Surfactant 1 | 4.2 | 4.2 | 4.2 | 4.2 | 4.2 | 4.2 | 4.2 | 4.2 |
| Silane coupling agent | 0.4 | 0.4 | 0.4 | 0.4 | 0.4 | 0.4 | 0.4 | 0.4 |
| 1 | | | | | | | | |
| Epoxy compound 1 | 0.4 | 0.4 | 0.4 | 0.4 | 0.4 | 0.4 | 0.4 | 0.4 |
| Solvent 1 | 13.3 | 7.9 | 5.7 | 3.4 | 13.3 | 7.9 | 5.7 | 3.4 |
| Solvent 2 | | | | | | | | |

TABLE 8

| | Example | Example | Example | Example | Example | Example | Example | Example |
|---|---|---|---|---|---|---|---|---|
| | 17 | 18 | 19 | 20 | 21 | 22 | 23 | 24 |
| Dispersion liquid 1 | | | | | | | | |
| Dispersion liquid 2 | | | | | | | | |
| Dispersion liquid 3 | | | | | | | | |
| Dispersion liquid 4 | | | | | | | | |
| Dispersion liquid 5 | | | | | | | | |
| Dispersion liquid 6 | | | | | | | | |
| Dispersion liquid 7 | | | | | | | | |
| Dispersion liquid 8 | | | | | | | | |
| Dispersion liquid 9 | | | | | | | | |
| Dispersion liquid 10 | | | | | | | | |
| Dispersion liquid 11 | | | | | | | | |
| Dispersion liquid 12 | | | | | | | | |
| Dispersion liquid 13 | | | | | | | | |
| Dispersion liquid 14 | | | | | | | | |
| Dispersion liquid 15 | | | | | | | | |
| Dispersion liquid 16 | | | | | | | | |
| Dispersion liquid 17 | 87.7 | | | | | | | |
| Dispersion liquid 18 | | 87.7 | | | | | | |
| Dispersion liquid 19 | | | 87.7 | | | | | |
| Dispersion liquid 20 | | | | 87.7 | | | | |
| Dispersion liquid 21 | | | | | 87.7 | | | |
| Dispersion liquid 22 | | | | | | 87.7 | | |
| Dispersion liquid 23 | | | | | | | 87.7 | |
| Dispersion liquid 24 | | | | | | | | 87.7 |
| Dispersion liquid 25 | | | | | | | | |
| Dispersion liquid 26 | | | | | | | | |
| Dispersion liquid 27 | | | | | | | | |
| Dispersion liquid 28 | | | | | | | | |
| Dispersion liquid 29 | | | | | | | | |
| Dispersion liquid 30 | | | | | | | | |
| Dispersion liquid 31 | | | | | | | | |
| Dispersion liquid 32 | | | | | | | | |
| Dispersion liquid 33 | | | | | | | | |
| Dispersion liquid 34 | | | | | | | | |
| Dispersion liquid 35 | | | | | | | | |
| Dispersion liquid c1 | | | | | | | | |
| Resin 1 | 0.2 | 0.2 | 0.2 | 0.2 | 0.2 | 0.2 | 0.2 | 0.2 |
| Resin 2 | | | | | | | | |
| Polymerizable | 1.1 | 1.1 | 1.1 | 1.1 | 1.1 | 1.1 | 1.1 | 1.1 |
| compound 1 | | | | | | | | |
| Polymerizable | | | | | | | | |
| compound 2 | | | | | | | | |
| Photopolymerization | 0.4 | 0.4 | 0.4 | 0.4 | 0.4 | 0.4 | 0.4 | 0.4 |
| initiator 1 | | | | | | | | |
| Photopolymerization | | | | | | | | |
| initiator 2 | | | | | | | | |
| Photopolymerization | | | | | | | | |
| initiator 3 | | | | | | | | |
| Surfactant 1 | 4.2 | 4.2 | 4.2 | 4.2 | 4.2 | 4.2 | 4.2 | 4.2 |
| Silane coupling agent | 0.4 | 0.4 | 0.4 | 0.4 | 0.4 | 0.4 | 0.4 | 0.4 |
| 1 | | | | | | | | |
| Epoxy compound 1 | 0.4 | 0.4 | 0.4 | 0.4 | 0.4 | 0.4 | 0.4 | 0.4 |
| Solvent 1 | 5.7 | 5.7 | 5.7 | 5.7 | 5.7 | 5.7 | 5.7 | 5.7 |
| Solvent 2 | | | | | | | | |

TABLE 9

| | Example | Example | Example | Example | Example | Example | Example | Example |
|---|---|---|---|---|---|---|---|---|
| | 25 | 26 | 27 | 28 | 29 | 30 | 31 | 32 |
| Dispersion liquid 1 | | | | | | | | |
| Dispersion liquid 2 | | | | | | | | |
| Dispersion liquid 3 | | | | | | | | |
| Dispersion liquid 4 | | | | | | | | |
| Dispersion liquid 5 | | | | | | | | |
| Dispersion liquid 6 | | | | | | | | |
| Dispersion liquid 7 | | | | | | | | |
| Dispersion liquid 8 | | | | | | | | |
| Dispersion liquid 9 | | | | | | | | |
| Dispersion liquid 10 | | | | | | | | |
| Dispersion liquid 11 | | | | | | | | |
| Dispersion liquid 12 | | | | | | | | |
| Dispersion liquid 13 | | | | | | | | |
| Dispersion liquid 14 | | | | | | | | |
| Dispersion liquid 15 | | | | | | | | |
| Dispersion liquid 16 | | | | | | | | |
| Dispersion liquid 17 | | | | | | | | |
| Dispersion liquid 18 | | | | | | | | |
| Dispersion liquid 19 | | | | | | | | |
| Dispersion liquid 20 | | | | | | | | |
| Dispersion liquid 21 | | | | | | | | |
| Dispersion liquid 22 | | | | | | | | |
| Dispersion liquid 23 | | | | | | | | |
| Dispersion liquid 24 | | | | | | | | |
| Dispersion liquid 25 | 85.0 | | | | | | | |
| Dispersion liquid 26 | | 85.0 | | | | | | |
| Dispersion liquid 27 | | | 85.0 | | | | | |
| Dispersion liquid 28 | | | | 85.0 | | | | |
| Dispersion liquid 29 | | | | | 78.2 | | | |
| Dispersion liquid 30 | | | | | | 78.2 | | |
| Dispersion liquid 31 | | | | | | | 78.2 | |
| Dispersion liquid 32 | | | | | | | | 78.2 |
| Dispersion liquid 33 | | | | | | | | |
| Dispersion liquid 34 | | | | | | | | |
| Dispersion liquid 35 | | | | | | | | |
| Dispersion liquid c1 | | | | | | | | |
| Resin 1 | 0.2 | 0.2 | 0.2 | 0.2 | 0.3 | 0.3 | 0.3 | 0.3 |
| Resin 2 | | | | | | | | |
| Polymerizable | 1.5 | 1.5 | 1.5 | 1.5 | 2.5 | 2.5 | 2.5 | 2.5 |
| compound 1 | | | | | | | | |
| Polymerizable | | | | | | | | |
| compound 2 | | | | | | | | |
| Photopolymerization | 0.5 | 0.5 | 0.5 | 0.5 | 0.8 | 0.8 | 0.8 | 0.8 |
| initiator 1 | | | | | | | | |
| Photopolymerization | | | | | | | | |
| initiator 2 | | | | | | | | |
| Photopolymerization | | | | | | | | |
| initiator 3 | | | | | | | | |
| Surfactant 1 | 4.2 | 4.2 | 4.2 | 4.2 | 4.2 | 4.2 | 4.2 | 4.2 |
| Silane coupling agent | 0.4 | 0.4 | 0.4 | 0.4 | 0.4 | 0.4 | 0.4 | 0.4 |
| 1 | | | | | | | | |
| Epoxy compound 1 | 0.4 | 0.4 | 0.4 | 0.4 | 0.4 | 0.4 | 0.4 | 0.4 |
| Solvent 1 | 7.9 | 7.9 | 7.9 | 7.9 | 13.3 | 13.3 | 13.3 | 13.3 |
| Solvent 2 | | | | | | | | |

TABLE 10

| | Example | Example | Example | Example | Example | Example | Example | Example | Comparative |
|---|---|---|---|---|---|---|---|---|---|
| | 33 | 34 | 35 | 36 | 37 | 38 | 39 | 40 | Example 1 |
| Dispersion liquid 1 | | | | | | | | | |
| Dispersion liquid 2 | 85.0 | 85.0 | 85.0 | 85.0 | 85.0 | | | | |
| Dispersion liquid 3 | | | | | | | | | |
| Dispersion liquid 4 | | | | | | | | | |
| Dispersion liquid 5 | | | | | | | | | |
| Dispersion liquid 6 | | | | | | | | | |
| Dispersion liquid 7 | | | | | | | | | |
| Dispersion liquid 8 | | | | | | | | | |
| Dispersion liquid 9 | | | | | | | | | |
| Dispersion liquid 10 | | | | | | | | | |
| Dispersion liquid 11 | | | | | | | | | |
| Dispersion liquid 12 | | | | | | | | | |
| Dispersion liquid 13 | | | | | | | | | |
| Dispersion liquid 14 | | | | | | | | | |
| Dispersion liquid 15 | | | | | | | | | |
| Dispersion liquid 16 | | | | | | | | | |
| Dispersion liquid 17 | | | | | | | | | |
| Dispersion liquid 18 | | | | | | | | | |
| Dispersion liquid 19 | | | | | | | | | |
| Dispersion liquid 20 | | | | | | | | | |
| Dispersion liquid 21 | | | | | | | | | |
| Dispersion liquid 22 | | | | | | | | | |
| Dispersion liquid 23 | | | | | | | | | |
| Dispersion liquid 24 | | | | | | | | | |
| Dispersion liquid 25 | | | | | | | | | |
| Dispersion liquid 26 | | | | | | | | | |
| Dispersion liquid 27 | | | | | | | | | |
| Dispersion liquid 28 | | | | | | | | | |
| Dispersion liquid 29 | | | | | | | | | |
| Dispersion liquid 30 | | | | | | | | | |
| Dispersion liquid 31 | | | | | | | | | |
| Dispersion liquid 32 | | | | | | | | | |
| Dispersion liquid 33 | | | | | | 85.0 | | | |
| Dispersion liquid 34 | | | | | | | 85.0 | | |
| Dispersion liquid 35 | | | | | | | | 78.2 | |
| Dispersion liquid c1 | | | | | | | | | 78.2 |
| Resin 1 | 0.1 | 0.2 | 0.2 | 0.2 | 0.2 | 0.2 | 0.2 | 0.3 | 0.3 |
| Resin 2 | 0.1 | | | | | | | | |
| Polymerizable | 1.5 | 0.8 | 1.5 | 1.5 | 1.5 | 1.5 | 1.5 | 2.5 | 2.5 |
| compound 1 | | | | | | | | | |
| Polymerizable | | 0.8 | | | | | | | |
| compound 2 | | | | | | | | | |
| Photopolymerization | 0.5 | 0.5 | 0.2 | 0.5 | | 0.5 | 0.5 | 0.8 | 0.8 |
| initiator 1 | | | | | | | | | |
| Photopolymerization | | | 0.2 | | | | | | |
| initiator 2 | | | | | | | | | |
| Photopolymerization | | | | | 0.5 | | | | |
| initiator 3 | | | | | | | | | |
| Surfactant 1 | 4.2 | 4.2 | 4.2 | 4.2 | 4.2 | 4.2 | 4.2 | 4.2 | 4.2 |
| Silane coupling agent | 0.4 | 0.4 | 0.4 | 0.4 | 0.4 | 0.4 | 0.4 | 0.4 | 0.4 |
| 1 | | | | | | | | | |
| Epoxy compound 1 | 0.4 | 0.4 | 0.4 | 0.4 | 0.4 | 0.4 | 0.4 | 0.4 | 0.4 |
| Solvent 1 | 7.9 | 7.9 | 7.9 | 4.0 | 7.9 | 7.9 | 7.9 | 13.3 | 13.3 |
| Solvent 2 | | | | 4.0 | | | | | |

The raw materials described by abbreviations shown in the above tables are as follows.

(Dispersion Liquid)

Dispersion liquids 1 to 35, cl: dispersion liquids 1 to 35 and cl described above

(Resin)

Resin 1: 40% by mass PGMEA solution of a resin having the following structure (the numerical value described together with the main chain indicates a molar ratio; weight-average molecular weight=11000)

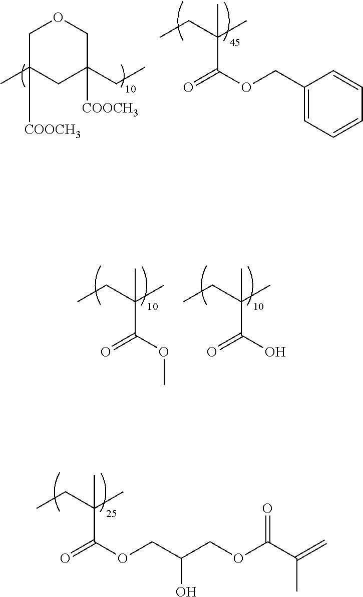

Resin 2: 70.0 parts by mass of cyclohexanone was charged into a separable four-neck flask equipped with a thermometer, a cooling pipe, a nitrogen gas introduction pipe, a dropping tube, and a stirrer, and was heated to 80° C., and after replacing the inside of the flask with nitrogen, from the dropping tube, a mixture of 13.3 parts by mass of n-butyl methacrylate, 4.6 parts by mass of 2-hydroxyethyl methacrylate, 4.3 parts by mass of methacrylic acid, 7.4 parts by mass of para-cumylphenol ethyleneoxide-modified acrylate (ARONIX M110 manufactured by TOAGOSEI CO., LTD.), and 0.4 parts by mass of 2,2′-azobisisobutyronitrile was added dropwise thereto over 2 hours. After the completion of the dropwise addition, the reaction was performed for 3 hours to obtain a resin P2. PGMEA was added thereto to adjust the concentration of solid contents to be 30% by mass, thereby obtaining a resin solution (30% by mass PGMEA solution of the resin P2). A weight-average molecular weight of the resin P2 was 26000. This resin solution was used as the resin 2.

(Polymerizable Compound)

Polymerizable compound 1: compound having the following structure

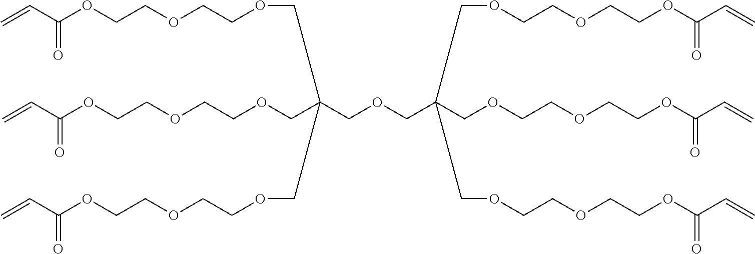 [SMILES: C=CC(=O)OCCOCCOCCCC(CCCOCCOCCOC(=O)C=C)(COCCOCCOC(=O)C=C)COCC(CCCOCCOCCOC(=O)C=C)(CCCOCCOCCOC(=O)C=C)COCCOCCOC(=O)C=C]

Polymerizable compound 2: mixture of compounds having the following structures (mixture in which a molar ratio of a compound on the left (hexafunctional (meth)acrylate compound) and a compound on the right (pentafuctional (meth)acrylate compound) was 7:3)

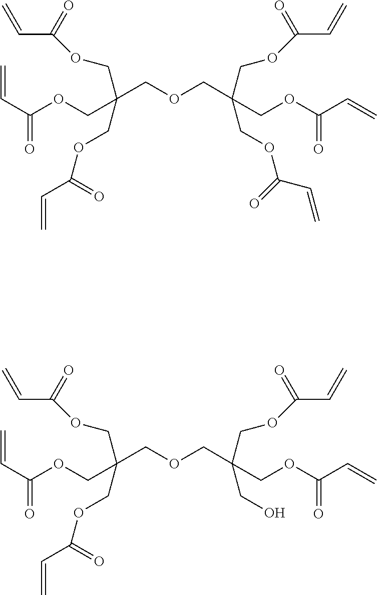 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

(Photopolymerization Initiator)

Photopolymerization initiator 1: compound having the following structure

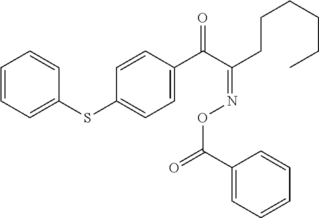 [SMILES: CCCCCC/C(=N/OC(=O)c1ccccc1)C(=O)c1ccc(Sc2ccccc2)cc1]

Photopolymerization initiator 2: compound having the following structure

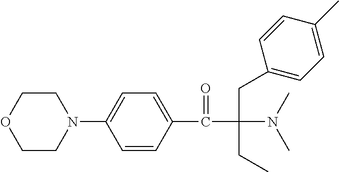 [SMILES: CCC(Cc1ccc(C)cc1)(C(=O)c1ccc(N2CCOCC2)cc1)N(C)C]

Photopolymerization initiator 3: compound having the following structure

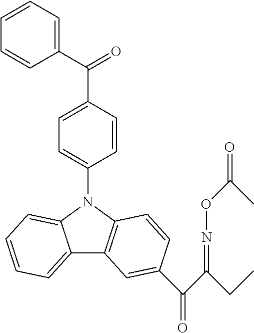 [SMILES: CCC(=NOC(C)=O)C(=O)c1ccc2c(c1)c1ccccc1n2-c1ccc(C(=O)c2ccccc2)cc1]

(Surfactant)

Surfactant 1: 1% by mass PGMEA solution of the following mixture (weight-average molecular weight=14000); in the following formula, % representing the proportion of a repeating unit is % by mass

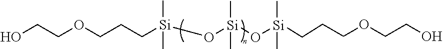

(Silane Coupling Agent)

Silane coupling agent 1: 0.2% by mass PGMEA solution of the following compound (weight-average molecular weight=3000)

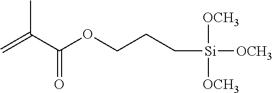 [SMILES: C=C(C)C(=O)OCCC[Si](OC)(OC)OC]

(Epoxy Compound)

Epoxy compound 1: EHPE-3150 (manufactured by Daicel Corporation)

(Solvent)

Solvent 1: PGMEA

Solvent 2: cyclohexanone

<Performance Evaluation of Coloring Composition>

[Evaluation of Long-Term Reliability]

The coloring composition shown in the above tables was applied onto an 8-inch (20.32 cm) glass wafer by a spin coating method so as to be 0.65 μm after post-baking, and then heated at 100° C. for 2 minutes using a hot plate to form a coloring composition layer. Next, using an i-ray stepper exposure device FPA-3000 i5+(manufactured by Canon Inc.), the above-described coloring composition layer was exposed through a mask having a Bayer pattern with an exposure amount of 300 mJ/cm². Next, a puddle development was performed to the coloring composition layer at 23° C. for 60 seconds using a 0.3% by mass aqueous solution of tetramethylammonium hydroxide (TMAH). Thereafter, rinsing with a spin shower and washing with pure water were performed thereto, and the glass wafer was further heated (post-baked) at 200° C. for 5 minutes using a hot plate, thereby forming a first pixel on the glass wafer. Subsequently, using a radiation-sensitive composition described in paragraph No. 0231 of JP2013-254047A, development and exposure were performed in the same manner as in the formation of the first pixel, thereby forming a second pixel (transparent pixel) in a missing portion of the Bayer pattern of the first pixel on the glass wafer. Using a microscopic spectrophotometer (“OSP-SP200” manufactured by Olympus Corporation), a transmittance (initial spectroscopy) of the second pixel at light having a wavelength of 400 to 700 nm was measured.

Next, a reliability test was performed by allowing the glass wafer on which the first pixel and the second pixel were formed to stand for 1500 hours under the conditions of a temperature of 85° C. and a relative humidity of 85%, and using a microscopic spectrophotometer (“OSP-SP200” manufactured by Olympus Corporation), a transmittance (spectroscopy after the reliability test) of the second pixel at the light having a wavelength of 400 to 700 nm was measured at a position 2 μm away from the boundary with the first pixel.

An amount of change in transmittance of the second pixel at the light having a wavelength of 400 to 700 nm before and after the test (=|Transmittance (%) of second pixel before reliability test−Transmittance (%) of second pixel after reliability test|) was calculated to obtain the maximum value (ΔTₘₐₓ₁) of the amount of change in transmittance, and a long-term reliability was evaluated according to the following standard. As the value of ΔTₘₐₓ₁ is smaller, the long-term reliability is excellent.

5: ΔTₘₐₓ₁ was 0.5% or less.

4: ΔTₘₐₓ₁ was more than 0.5% and 1% or less.

3: ΔTₘₐₓ₁ was more than 1% and 3% or less.

2: ΔTₘₐₓ₁ was more than 3% and 5% or less.

1: ΔTₘₐₓ₁ was more than 5%.

[Evaluation of Light Resistance]

The coloring composition shown in the above tables was applied onto an 8-inch (20.32 cm) glass wafer by a spin coating method so as to be 0.65 μm after post-baking, and then heated at 100° C. for 2 minutes using a hot plate to form a coloring composition layer. Next, using an i-ray stepper exposure device FPA-3000 i5+(manufactured by Canon Inc.), the coloring composition layer was irradiated exposed with an exposure amount of 300 mJ/cm². Next, a puddle development was performed to the composition layer at 23° C. for 60 seconds using a 0.3% by mass aqueous solution of tetramethylammonium hydroxide (TMAH). Thereafter, rinsing with a spin shower and washing with pure water were performed thereto, and the glass wafer was further heated (post-baked) at 200° C. for 5 minutes using a hot plate, thereby forming a film. A transmittance of the obtained film was measured using MCPD3700 (manufactured by OTSUKA ELECTRONICS CO., LTD.).

Using Super Xenon Weather Meter SX75 (manufactured by Suga Test Instruments Co., Ltd.), the above-described film was irradiated with light at an illuminance of 100000 lux for 1500 hours to perform a light resistance test. A transmittance of the film of the light resistance test was measured using MCPD3700 (manufactured by OTSUKA ELECTRONICS CO., LTD.).

An amount of change in transmittance of the film at the light having a wavelength of 400 to 700 nm before and after the test (=|Transmittance (%) of film before light resistance test−Transmittance (%) of film after light resistance test|) was calculated to obtain the maximum value (ΔTₘₐₓ₂) of the amount of change in transmittance, and a light resistance was evaluated according to the following standard. As the value of ΔTₘₐₓ₂ is smaller, the light resistance is excellent.

5: ΔTₘₐₓ₂ was 5% or less.

4: ΔTₘₐₓ₂ was more than 5% and 10% or less.

3: ΔTₘₐₓ₂ was more than 10% and 20% or less.

2: ΔTₘₐₓ₂ was more than 20% and 25% or less.

1: ΔTₘₐₓ₂ was more than 25% and 30% or less.

0: ΔTₘₐₓ₂ was more than 30%.

The evaluation results of the long-term reliability and the light resistance are shown in the following tables. The following tables also show the content (yellow colorant ratio in the tables) of the yellow colorant in the colorant and the content (azomethine metal complex ratio in the tables) of the azomethine metal complex in the yellow colorant, which are used in each coloring composition. In addition, the coloring compositions of Examples 1 to 28 and 32 to 40 were applied onto an 8-inch (20.32 cm) glass wafer by a spin coating method, heated at 100° C. for 2 minutes using a hot plate, and then heated at 200° C. for 5 minutes to form a film having a thickness of 0.65 For the film, a transmittance of light having a wavelength of 470 to 520 nm was measured, and a value of a wavelength at which the transmittance was 50% was described in the column of “Wavelength at 50% transmittance (nm)” in the following tables.

TABLE 11

| | Example | Example | Example | Example | Example | Example | Example | Example |
|---|---|---|---|---|---|---|---|---|
| | 1 | 2 | 3 | 4 | 5 | 6 | 7 | 8 |
| Yellow colorant ratio | 33% | 37% | 43% | 47% | 33% | 37% | 43% | 47% |
| Azomethine metal complex ratio | 27% | 47% | 54% | 63% | 27% | 47% | 54% | 63% |
| Long-term reliability | 2 | 3 | 4 | 5 | 2 | 3 | 4 | 5 |
| Light resistance | 2 | 2 | 3 | 4 | 2 | 3 | 4 | 5 |
| Wavelength at 50% transmittance (nm) | 510 | 510 | 510 | 510 | 510 | 509 | 510 | 510 |

TABLE 12

| | Example | Example | Example | Example | Example | Example | Example | Example |
|---|---|---|---|---|---|---|---|---|
| | 9 | 10 | 11 | 12 | 13 | 14 | 15 | 16 |
| Yellow colorant ratio | 33% | 37% | 43% | 47% | 33% | 37% | 43% | 47% |
| Azomethine metal complex ratio | 27% | 47% | 54% | 63% | 27% | 47% | 54% | 63% |
| Long-term reliability | 2 | 3 | 4 | 5 | 2 | 3 | 4 | 5 |
| Light resistance | 3 | 4 | 5 | 5 | 4 | 5 | 5 | 5 |
| Wavelength at 50% transmittance (nm) | 483 | 486 | 488 | 490 | 483 | 486 | 488 | 489 |

TABLE 13

| | Example | Example | Example | Example | Example | Example | Example | Example |
|---|---|---|---|---|---|---|---|---|
| | 17 | 18 | 19 | 20 | 21 | 22 | 23 | 24 |
| Yellow colorant ratio | 39% | 37% | 36% | 34% | 39% | 37% | 36% | 34% |
| Azomethine metal complex ratio | 48% | 52% | 41% | 32% | 48% | 52% | 41% | 32% |
| Long-term reliability | 3 | 4 | 3 | 2 | 3 | 4 | 3 | 2 |
| Light resistance | 3 | 4 | 3 | 3 | 4 | 5 | 4 | 3 |
| Wavelength at 50% transmittance (nm) | 486 | 487 | 487 | 487 | 486 | 487 | 487 | 488 |

TABLE 14

| | Example | Example | Example | Example | Example | Example | Example | Example |
|---|---|---|---|---|---|---|---|---|
| | 25 | 26 | 27 | 28 | 29 | 30 | 31 | 32 |
| Yellow colorant ratio | 37% | 37% | 37% | 37% | 33% | 33% | 33% | 33% |
| Azomethine metal complex ratio | 47% | 47% | 47% | 47% | 100% | 100% | 100% | 60% |
| Long-term reliability | 3 | 3 | 3 | 3 | 5 | 5 | 5 | 5 |
| Light resistance | 2 | 2 | 2 | 4 | 5 | 5 | 5 | 2 |
| Wavelength at 50% transmittance (nm) | 510 | 510 | 510 | 510 | — | — | — | 484 |

TABLE 15

| | Example | Example | Example | Example | Example | Example | Example | Example | Comparative |
|---|---|---|---|---|---|---|---|---|---|
| | 33 | 34 | 35 | 36 | 37 | 38 | 39 | 40 | Example 1 |
| Yellow colorant ratio | 37% | 37% | 37% | 37% | 33% | 37% | 37% | 37% | 28% |
| Azomethine metal complex ratio | 47% | 47% | 47% | 47% | 30% | 47% | 47% | 47% | 14% |
| Long-term reliability | 3 | 3 | 3 | 3 | 2 | 4 | 3 | 3 | 1 |
| Light resistance | 2 | 2 | 2 | 2 | 1 | 2 | 2 | 2 | 0 |
| Wavelength at 50% transmittance (nm) | 510 | 510 | 510 | 510 | 510 | 510 | 510 | 479 | 476 |

As shown in the above tables, with the coloring compositions of Examples, a film having excellent long-term reliability could be formed.

### Example 1001

A silicon wafer was coated with a green coloring composition by a spin coating method so that a thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the green coloring composition was patterned by heating at 200° C. for 5 minutes using a hot plate to form a green pixel. In the same process, a red coloring composition and a blue coloring composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the green coloring composition, the coloring composition of Example 2 was used. As the red coloring composition, the coloring composition of Example 29 was used. The blue coloring composition will be described later.

(Preparation of Blue Coloring Composition)

The following components were mixed and stirred, and the obtained mixture was filtered through a nylon filter (manufactured by Nihon Pall Corporation) having a pore size of 0.45 μm to prepare the blue coloring composition.

Blue pigment dispersion liquid: 30.47 parts by mass

Dye 1: 2.64 parts by mass

Resin 1: 0.01 parts by mass

Resin 3: 0.04 parts by mass

Polymerizable compound 3: 1.56 parts by mass

Photopolymerization initiator 4: 0.57 parts by mass

Additive 1: 0.35 parts by mass

Epoxy compound 2: 0.46 parts by mass

Surfactant 101: 2.00 parts by mass (as 1% by mass PGMEA solution)

PGMEA: 5.70 parts by mass

Cyclohexanone: 55.4 parts by mass

Propylene glycol monomethyl ether: 0.8 parts by mass

Raw materials used to prepare the blue coloring composition are as follows.

Blue Pigment Dispersion Liquid

A mixed solution consisting of 15 parts by mass of C. I. Pigment Blue 15:6, 2.2 parts by mass of a dispersant (Disperbyk-161, manufactured by BYK Chemie), 2.2 parts by mass of a resin 3, and 80.6 parts by mass of the solvent 1 was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm² at a flow rate of 500 g/min. This dispersion treatment was repeated 10 times, thereby obtaining the blue pigment dispersion liquid.

Dye 1: xanthene dye polymer represented by the following formula (weight-average molecular weight: 7,400, acid value: 0.8 mmol/g, C═C bond equivalent: 0.78 mmol/g; in the following structural formula, iPr is an isopropyl group)

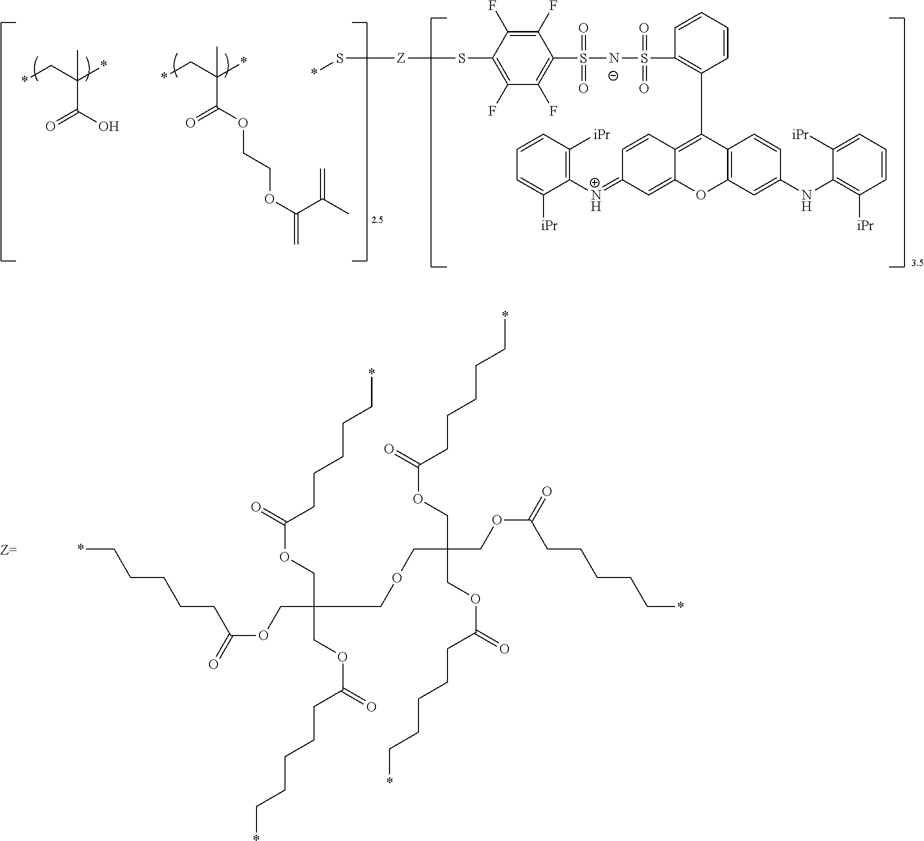

Resin 1: 40% by mass PGMEA solution of a resin having the following structure (the numerical value described together with the main chain indicates a molar ratio; weight-average molecular weight=11000)

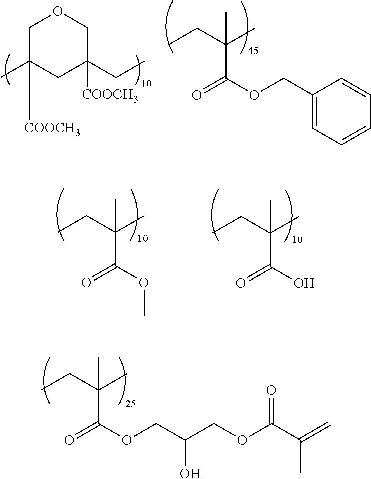

Resin 3: resin having the following structure (the numerical value described together with the main chain indicates a molar ratio; weight-average molecular weight=11000, acid value=200 mgKOH/g)

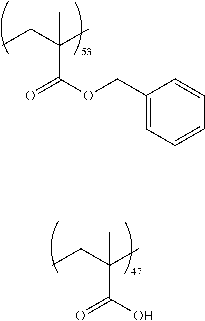

Polymerizable compound 3: compound having the following structure

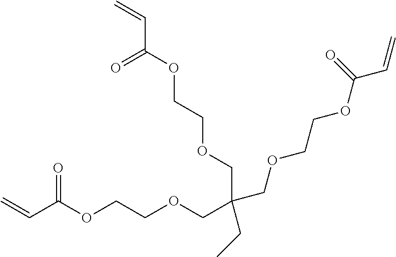 [SMILES: C=CC(=O)OCCOCC(CC)(COCCOC(=O)C=C)COCCOC(=O)C=C]

Photopolymerization initiator 4: compound having the following structure

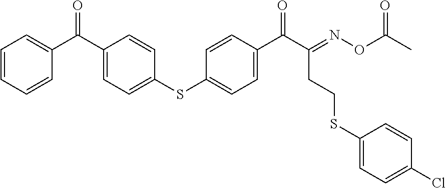 [SMILES: CC(=O)O/N=C(\CCSc1ccc(Cl)cc1)C(=O)c1ccc(Sc2ccc(C(=O)c3ccccc3)cc2)cc1]

Additive 1: compound having the following structure (potassium N,N-bis(pentafluoroethanesulfonyl)imide)

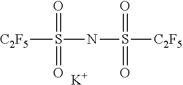

Epoxy compound 2: compound having the following structure

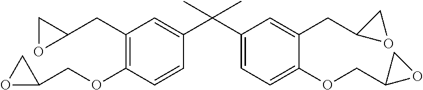 [SMILES: CC(C)(c1ccc(OCC2CO2)c(CC2CO2)c1)c1ccc(OCC2CO2)c(CC2CO2)c1]

Surfactant 101: 1% by mass PGMEA solution of a compound having the following structure (weight-average molecular weight: 14000; the numerical value “%” representing the proportion of the repeating unit is mol %)

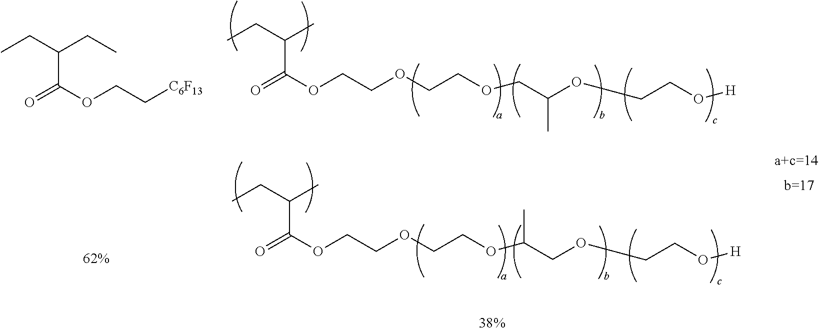

What is claimed is:

1. A coloring composition comprising:
a colorant including a yellow colorant;
a resin; and
a solvent,
wherein a content of the yellow colorant in the colorant is 30% by mass or more, and
the yellow colorant includes 15% by mass or more of an azomethine metal complex.

2. The coloring composition according to claim 1,
wherein a content of a quinophthalone compound in the yellow colorant is less than 50% by mass.

3. The coloring composition according to claim 1,
wherein the azomethine metal complex includes at least one selected from an azomethine copper complex or an azomethine zinc complex.

4. The coloring composition according to claim 1,
wherein the colorant includes at least one selected from a green colorant or a red colorant.

5. The coloring composition according to claim 1,
wherein the colorant includes a green colorant, and
the green colorant includes a phthalocyanine compound.

6. The coloring composition according to claim 1,
wherein, in a case where a film having a thickness of 0.65 μm is formed of the coloring composition, a wavelength at which a light transmittance of the film is 50% exists in a wavelength range of 470 to 520 nm.

7. The coloring composition according to claim 1, further comprising:
a polymerizable compound; and
a photopolymerization initiator.

8. The coloring composition according to claim 1,
wherein the coloring composition is used for a color filter or an infrared transmitting filter.

9. A film obtained from the coloring composition according to claim 1.

10. An optical filter comprising:
the film according to claim 9.

11. A solid-state imaging element comprising:
the film according to claim 9.

12. An image display device comprising:
the film according to claim 9.
